(19) United States
(12) Patent Application Publication
(10) Pub. No.: US 2024/0287315 A1
(43) Pub. Date: Aug. 29, 2024

(54) PRIMER COMPOSITION FOR INORGANIC OXIDE CURED PRODUCT, AND MULTILAYER BODY

(71) Applicant: DIC Corporation, Tokyo (JP)

(72) Inventors: Kenichirou OKA, Chiba (JP); Yasuhiro TAKADA, Chiba (JP)

(73) Assignee: DIC Corporation, Tokyo (JP)

(21) Appl. No.: 18/570,609

(22) PCT Filed: Jun. 9, 2022
(86) PCT No.: PCT/JP2022/023218

§ 371 Date: Dec. 14, 2023

(30) Foreign Application Priority Data
Jun. 17, 2021 (JP) 2021-100875

(51) Int. Cl. C09D 5/00; C08K 3/36; C09D 143/04; C09D 151/10; C23C 14/02; C23C 14/10

(52) U.S. Cl. CPC C09D 5/002; C09D 143/04; C09D 151/10; C23C 14/021; C23C 14/10; C08K 3/36

(57) ABSTRACT

Provided are a primer composition for inorganic oxide containing a polysiloxane compound (A), a compound having a reactive group (B) that is not (A), and inorganic oxide fine particles (C), (A) having a vinyl group and/or an epoxy group, a structural unit represented by a formula (1) and/or a formula (2), and a silanol group and/or a hydrolyzable silyl group, wherein a content of (A) is 2.5 to 40 mass % relative to a sum of (A) to (C), a cured product obtained by curing the composition, and a multilayer body having a curable resin layer obtained by curing the composition (R¹ to R³ are a group having a specific polymerizable double bond, or an alkyl group, a cycloalkyl group, an aryl group, an aralkyl group, or an epoxy group).

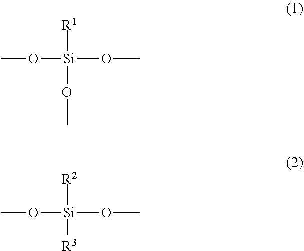

### TECHNICAL FIELD

The present invention relates to a primer composition for inorganic oxide vapor deposition, a cured product obtained by curing the primer composition, and a multilayer body having a curable resin layer obtained by curing the primer composition.

### BACKGROUND ART

In recent years, the demand for flat panel displays has increased with development of personal computers, particularly with development of portable personal computers. Recently, the penetration rate of flat panel televisions for home use has also increased, and the market of flat panel displays has increasingly expanded. Flat panel displays that spread in recent years have a tendency of having a large screen, and the tendency is increased especially in liquid crystal televisions for home use.

For such a flat panel display, various display modes such as modes of a liquid crystal display, a plasma display, and an organic EL display are adopted. In displays of all the display modes, studies to improve the display quality of images have been carried out.

In particular, the development of a light antireflection technique for improvement in display quality is one critical technical problem common in the displays of all the display modes. Conventionally, as such an antireflection technique, for example, a technique in which a single layer of a thin film formed from a substance with low refractive index is formed on a surface to obtain an antireflection effect effective to light having a single wavelength, or a technique in which a plurality of layers obtained by alternately forming a thin layer of a substance with low refractive index and a thin layer of a substance with high refractive index are formed to obtain an antireflection effect against light having a wider wavelength range are used.

Among the techniques, the technique using a plurality of layers is useful in terms of obtaining an antireflection effect against light having a wider wavelength range when the number of the layers is increased. Therefore, efforts have been made to put the technique into practical use in various applications.

In the layers having an excellent antireflection effect, layers with different refractive indexes are layered on a film coated with a deposition primer by a vacuum evaporation method or the like. However, there is a problem in that an interface between a vapor deposited layer of an inorganic oxide layer and a primer layer is peeled depending on environmental conditions such as light, heat, and humidity.

In patent literature 1, an organic layer is formed from a cured product of a resin composition containing urethane acrylate having a property of preventing decomposition with plasma (hereinafter sometimes simply referred to as “plasma resistance”) to improve a problem with delamination. In patent literature 2, metal oxide particles are exposed to a surface of a hardcoat layer containing the metal oxide particles to improve the problem with delamination. However, these cannot achieve close contact between the layers in a humid and hot environment described in the present application.

### CITATION LIST

### Patent Literature

Patent Literature 1: Japanese Unexamined Patent Application Publication No. 2017-165109

Patent Literature 2: Japanese Unexamined Patent Application Publication No. 2016-224443

### SUMMARY OF INVENTION

### Technical Problem

An object of the present invention is to provide a multilayer body having excellent adherence in an environment including a hot environment, a humid environment, and the like.

### Solution to Problem

The inventors of the present invention have intensively studied and as a result, found that a multilayer body obtained using a primer composition that includes combination of a polysiloxane compound and inorganic oxide fine particles and contains the polysiloxane compound at a specific proportion is excellent in adherence under various environmental conditions.

The present invention provides the following inventions.

(1) A primer composition for inorganic oxide vapor deposition containing: a polysiloxane compound (A); a compound having a reactive group (B) that is not the polysiloxane compound (A); and inorganic oxide fine particles (C),
the polysiloxane compound (A) having a vinyl group and/or an epoxy group, a structural unit represented by a general formula (1) and/or a general formula (2), and a silanol group and/or a hydrolyzable silyl group,
wherein a content of the polysiloxane compound (A) is 2.5 to 40 mass % relative to a sum of the polysiloxane compound (A), the compound (B), and the inorganic oxide fine particles (C).

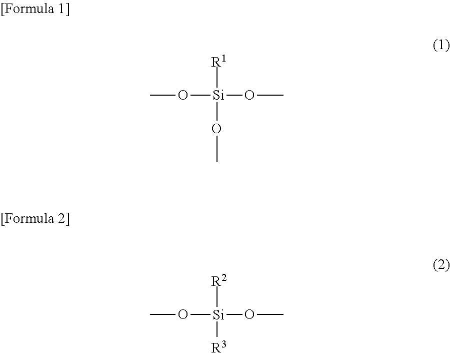

(In the general formulae (1) and (2), R¹, R², and R³ are each independently a group having a polymerizable double bond selected from the group consisting of —R⁴—CH═CH₂, —R⁴—C(CH₃)═CH₂, —R⁴—O—CO—C(CH₃)═CH₂, —R⁴—O—CO—CH═CH₂, and a group represented by a general formula (3) below, or an alkyl group having 1 to 6 carbon atoms, a cycloalkyl group having 3 to 8 carbon atoms, an aryl group, an aralkyl group having 7 to 12 carbon atoms, or an epoxy group, and each R⁴ is independently a single bond or an alkylene group having 1 to 6 carbon atoms.)

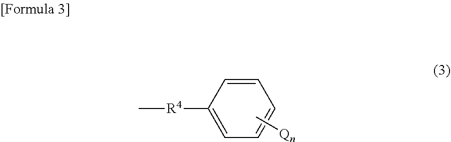

(In the general formula (3), n is an integer of 1 to 5, a structure Q is —CH═CH₂ or —C(CH₃)═CH₂, and R⁴ is the same as described above.)

(2) The primer composition according to (1), wherein a ratio by mass (A)/(C) of a solid content of the polysiloxane compound (A) to a solid content of the inorganic oxide fine particles (C) is 10/90 to 80/20, and
a total content of the inorganic oxide fine particles (C) and the polysiloxane compound (A) is 70 mass % or less relative to a total solid content of the primer composition.

(3) The primer composition according to (1) or (2), wherein the polysiloxane compound (A) is bonded to the inorganic oxide fine particles (C) through a siloxane bond to form an inorganic fine particle composite (D).

(4) A cured product obtained by curing the primer composition according to any one of (1) to (3).

(5) A multilayer body including a curable resin layer (I) obtained by curing the primer composition according to any one of (1) to (3), and an inorganic oxide layer (II) containing an inorganic oxide.

(6) The multilayer body according to (5), further including a substrate layer, wherein the curable resin layer (I) and the inorganic oxide layer (II) are layered in this order on the substrate.

(7) The multilayer body according to (6), wherein the substrate is a film having a thickness of 10 μm to 1 mm.

### Advantageous Effects of Invention

The primer composition for inorganic oxide vapor deposition of the present invention can be suitably used to form a primer layer used in the formation of a vapor deposited layer that is formed from an inorganic oxide on a substrate.

The multilayer body including a curable resin layer (I) obtained by curing the primer composition for inorganic oxide vapor deposition of the present invention, and an inorganic oxide layer (II) containing an inorganic oxide can be suitably used as a functional film having excellent adherence under various environmental conditions.

In the multilayer body that further includes a substrate layer and in which the curable resin layer (I) and the inorganic oxide layer (II) are layered in this order on the substrate, the curable resin layer (I) and the inorganic oxide layer (II) can protect the substrate layer. In addition, when the curable resin layer (I) is disposed between the substrate layer and the inorganic oxide layer (II), the curable resin layer (I) enhances the adherence between the substrate layer and the inorganic oxide layer (II). Therefore, the layers are unlikely to be peeled even in an environment where heat and humidity are severe.

The multilayer body obtained using the primer composition for inorganic oxide vapor deposition of the present application is excellent in hardcoat properties, heat resistance, water resistance, and weather resistance, and therefore is particularly suitably usable as various functional materials and surface-protecting materials. For example, the multilayer body is usable for a building material, a housing facility, transport machines such as a vehicle, a ship, an aircraft, and a train, an electronic material, a recording material, an optical material, illumination, a packaging material, protection of an object mounted outside, covering an optical fiber, protection of resin glass, and the like. In particular, the multilayer body is suitably usable as an antireflective film of a liquid crystal display, a plasma display, further an organic EL display, and the like.

### DESCRIPTION OF EMBODIMENTS

### <Primer Composition for Inorganic Oxide Vapor Deposition>

A primer composition for inorganic oxide vapor deposition of the present invention (hereinafter sometimes simply referred to as “primer composition” or “composition”) contains a polysiloxane compound (A), a compound having a reactive group (B) that is not the polysiloxane compound (A), and inorganic oxide fine particles (C).

### [Polysiloxane Compound (A)]

The polysiloxane compound (A) (hereinafter sometimes simply referred to as “compound (A)” or “component (A)”) has a vinyl group and/or an epoxy group, a structural unit represented by a general formula (1) and/or a general formula (2), and a silanol group and/or a hydrolyzable silyl group.

In the present invention, the “vinyl group” involves the concept including a “CH₂═CH—” group obtained by removing one hydrogen atom from ethylene and a “CH₂═C(CH₃)—” group obtained by substituting one hydrogen atom of ethylene with a methyl group and removing one hydrogen atom.

(Vinyl Group and/or Epoxy Group)

Since the component (A) of the present invention has a vinyl group and/or an epoxy group, the primer composition can be cured by heating or an active energy ray. Two curing mechanisms including a cross-linking/polymerization reaction of a vinyl group and/or an epoxy group and a condensation reaction of a silanol group and/or a hydrolyzable silyl group described later can increase the cross-linking density of a cured product or a cured layer obtained, to form a multilayer body having a more excellent low linear expansion ratio.

The number of the vinyl groups and/or the epoxy groups in the component (A) is preferably 2 or more, more preferably 3 to 200, and further preferably 3 to 50. Specifically, when the content of the vinyl group and/or the epoxy group in the component (A) is 3 to 35 mass %, desired weather resistance can be achieved.

The component (A) may contain the vinyl group or the epoxy group as a part of the structural unit represented by the general formula (1) and/or the general formula (2) described later or as a structural unit different from the aforementioned structural unit. In particular, the component (A) preferably contains the vinyl group or the epoxy group as a part of the structural unit represented by the general formula (1) and/or the general formula (2).

(Structural Unit Represented by General Formula (1) and/or General Formula (2))

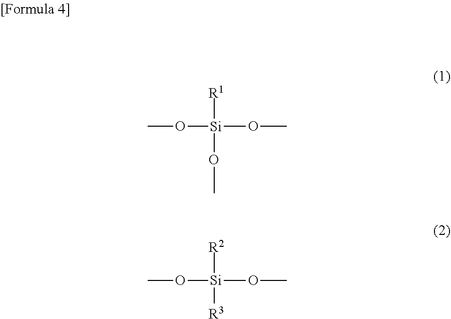

(In the general formulae (1) and (2), R¹, R², and R³ are each independently a group having a polymerizable double bond selected from the group consisting of —R⁴—CH═CH₂, —R⁴—C(CH₃)═CH₂, —R⁴—O—CO—C(CH₃)═CH₂, —R⁴—O—CO—CH═CH₂, and a group represented by a general formula (3) below, or an alkyl group having 1 to 6 carbon atoms, a cycloalkyl group having 3 to 8 carbon atoms, an aryl group, an aralkyl group having 7 to 12 carbon atoms, or an epoxy group, and each R⁴ is independently a single bond or an alkylene group having 1 to 6 carbon atoms.)

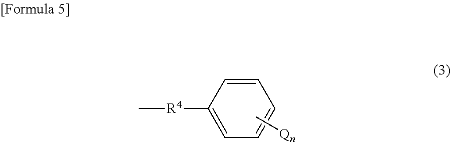

(In the general formula (3), n is an integer of 1 to 5, a structure Q is —CH═CH₂ or —C(CH₃)═CH₂, and R⁴ is the same as described above.)

The structural unit represented by the formula (1) and/or the formula (2) is a three-dimensional net-shaped polysiloxane structural unit in which two or three bonds of silicon are involved in cross-linking. A three-dimensional net structure is formed, but the formed net structure is not dense. Therefore, gelation and the like do not occur, and favorable storage stability is achieved.

Examples of the alkylene group having 1 to 6 carbon atoms as R⁴ when in the formulae (1) to (2), R¹ to R³ are —R⁴—CH═CH₂, —R⁴—C(CH₃)═CH₂, —R⁴—O—CO—C(CH₃)═CH₂, or —R⁴—O—CO—CH═CH₂ include a methylene group, an ethylene group, a propylene group, an isopropylene group, a butylene group, an isobutylene group, a sec-butylene group, a tert-butylene group, a pentylene group, an isopentylene group, a neopentylene group, a tert-pentylene group, a 1-methylbutylene group, a 2-methylbutylene group, a 1,2-dimethylpropylene group, a 1-ethylpropylene group, a hexylene group, an isohexylene group, a 1-methylpentylene group, a 2-methylpentylene group, a 3-methylpentylene group, a 1,1-dimethylbutylene group, a 1,2-dimethylbutylene group, a 2,2-dimethylbutylene group, a 1-ethylbutylene group, a 1,1,2-trimethylpropylene group, a 1,2,2-trimethylpropylene group, a 1-ethyl-2-methylpropylene group, and a 1-ethyl-1-methypropylene group. In particular, R⁴ is preferably a single bond or an alkylene group having 2 to 4 carbon atoms in terms of availability of a raw material.

When R¹ to R³ are the group represented by the formula (3), one to five structures Q may be bonded to an aromatic ring, and one to two structures Q are preferably bonded to the aromatic ring. When two Q are bonded to the aromatic ring, a structure represented by the following formula (5) is considered as an example.

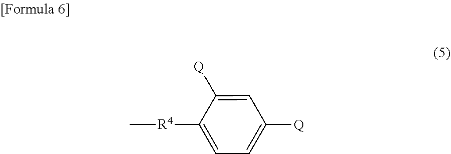

Since the structure typified by a styryl group contains no oxygen atom, oxidative destruction from an oxygen atom as a starting point is less likely to occur, and resistance to thermal decomposition is high. Therefore, this structure is suitable for use application requiring heat resistance. This is considered to be because a bulky structure inhibits a reaction that causes oxidation. A group having a polymerizable double bond including —CH═CH₂ and —C(CH₃)═CH₂ of the structure Q also contributes to enhancement in heat resistance.

Examples of the alkyl group having 1 to 6 carbon atoms as R¹ to R³ include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group.

Examples of the cycloalkyl group having 3 to 8 carbon atoms as R¹ to R³ include a cyclopropyl group, a cyclobutyl group, a cyclopentyl group, and a cyclohexyl group.

Examples of the aryl group as R¹ to R³ include a phenyl group, a naphthyl group, a 2-methylphenyl group, a 3-methylphenyl group, a 4-methylphenyl group, a 4-vinylphenyl group, and a 3-isopropylphenyl group.

Examples of the aralkyl group having 7 to 12 carbon atoms as R¹ to R³ include a benzyl group, a diphenylmethyl group, and a naphthylmethyl group.

In particular, when at least one of R¹ to R³ is a group having a polymerizable double bond or an epoxy group, it is not necessary that the component (A) contain “the vinyl group and/or the epoxy group” described above in addition to this structural unit. Therefore, it is preferable that in at least one structural unit represented by the formula (1) and/or the formula (2) in the component (A), at least one of R¹ to R³ be a group having a polymerizable double bond or an epoxy group.

When at least one of R¹ to R³ is a group having a polymerizable double bond or an epoxy group, the primer composition can be cured by an active energy ray and the like, and the two curing mechanisms including the curing by an active energy ray and a condensation reaction of the silanol group and/or the hydrolyzable silyl group increase the cross-linking density of a cured product obtained. Thus, a cured product having more excellent weather resistance can be formed.

(Silanol Group and/or Hydrolyzable Silyl Group)

In the present invention, a silanol group is a silicon-containing group having a hydroxy group directly bonded to a silicon atom. Specifically, the silanol group is preferably a silanol group that is generated by bonding an oxygen atom having a bond in the structural unit represented by the general formula (1) and/or the general formula (2) to a hydrogen atom.

In the present invention, a hydrolyzable silyl group is a silicon-containing group having a hydrolyzable group directly bonded to a silicon atom. Specific examples thereof include a group represented by a general formula (6).

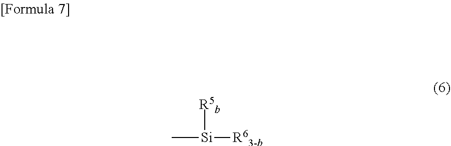

(In the formula (6), R⁵ is a monovalent organic group such as an alkyl group, an aryl group, or an aralkyl group, R⁶ is a hydrolyzable group selected from the group consisting of a halogen atom, an alkoxy group, an acyloxy group, a phenoxy group, an allyloxy group, a mercapto group, an amino group, an amido group, an aminooxy group, an iminooxy group, and an alkenyloxy group, and b is an integer of 0 to 2.)

Examples of the alkyl group as R⁵ include a methyl group, an ethyl group, a propyl group, an isopropyl group, a butyl group, an isobutyl group, a sec-butyl group, a tert-butyl group, a pentyl group, an isopentyl group, a neopentyl group, a tert-pentyl group, a 1-methylbutyl group, a 2-methylbutyl group, a 1,2-dimethylpropyl group, a 1-ethylpropyl group, a hexyl group, an isohexyl group, a 1-methylpentyl group, a 2-methylpentyl group, a 3-methylpentyl group, a 1,1-dimethylbutyl group, a 1,2-dimethylbutyl group, a 2,2-dimethylbutyl group, a 1-ethylbutyl group, a 1,1,2-trimethylpropyl group, a 1,2,2-trimethylpropyl group, a 1-ethyl-2-methylpropyl group, and a 1-ethyl-1-methylpropyl group.

Examples of the aryl group as R⁵ include a phenyl group, a naphthyl group, a 2-methylphenyl group, a 3-methylphenyl group, a 4-methylphenyl group, a 4-vinylphenyl group, and a 3-isopropylphenyl group.

Examples of the aralkyl group as R⁵ include a benzyl group, a diphenylmethyl group, and a naphthylmethyl group.

Examples of the halogen atom as R⁶ include a fluorine atom, a chlorine atom, a bromine atom, and an iodine atom.

Examples of the alkoxy group as R⁶ include a methoxy group, an ethoxy group, a propoxy group, an isopropoxy group, a butoxy group, a sec-butoxy group, and a tert-butoxy group. Examples of the acyloxy group include formyloxy, acetoxy, propanoyloxy, butanoyloxy, pivaloyloxy, pentanoyloxy, phenylacetoxy, acetoacetoxy, benzoyloxy, and naphthoyloxy. Examples of the allyloxy group include phenyloxy and naphthyloxy.

Examples of the alkenyloxy group as R⁶ include a vinyloxy group, an allyloxy group, a 1-propenyloxy group, an isopropenyloxy group, a 2-butenyloxy group, a 3-butenyloxy group, a 2-petenyloxy group, a 3-methyl-3-butenyloxy group, and a 2-hexenyloxy group.

When the hydrolyzable group represented by R⁶ is hydrolyzed, the hydrolyzable silyl group represented by the formula (6) is converted to a silanol group. Among them, from the viewpoint of excellent hydrolyzability, R⁶ is preferably a methoxy group or an ethoxy group.

Specifically, the hydrolyzable silyl group is preferably a hydrolyzable silyl group in which an oxygen atom having a bond in the structural unit represented by the general formula (1) and/or the general formula (2) is bonded to or substituted by the hydrolyzable group.

For the silanol group and the hydrolyzable silyl group, a hydrolysis-condensation reaction between a hydroxy group in the silanol group and the hydrolyzable group in the hydrolyzable silyl group promotes, and as a result, the cross-linking density of the polysiloxane structure is increased, to form a cured product having excellent weather resistance.

The component (A) is not particularly limited as long as the component (A) has the vinyl group and/or the epoxy group, the structural unit represented by the general formula (1) and/or the general formula (2), and the silanol group and/or the hydrolyzable silyl group. The component (A) may have another group. As an example, the component (A) may have a urethane bond, an ether bond, an amide bond, or an ester bond in the structure.

As the component (A), a commercially available product can be used. Examples thereof include X-12-1048 (available from Shin-Etsu Chemical Co., Ltd.), X-12-1050 (available from Shin-Etsu Chemical Co., Ltd.), KR-513 (available from Shin-Etsu Chemical Co., Ltd.), X-40-9308 (available from Shin-Etsu Chemical Co., Ltd.), KR-517 (available from Shin-Etsu Chemical Co., Ltd.), X-40-2670 (available from Shin-Etsu Chemical Co., Ltd.), X-24-9590 (available from Shin-Etsu Chemical Co., Ltd.), KR-516 (available from Shin-Etsu Chemical Co., Ltd.), X40-9296 (available from Shin-Etsu Chemical Co., Ltd.), TM-100 (available from TOAGOSEI CO., LTD.), TA-100 (available from TOAGOSEI CO., LTD.), M-100 (available from SiliXan GmbH), and M-140 (SiliXan GmbH).

The content of the compound (A) is 2.5 to 40 mass % relative to a sum of the compound (A), the compound (B) described later, and the inorganic oxide fine particles (C) described later. The lower limit value thereof is preferably 3 mass % or more, more preferably 5 mass % or more, and further preferably 8 mass % or more. The upper limit value thereof is preferably 35 mass % or less, and more preferably 30 mass % or less. From all the above, the content is preferably 2.5 to 35 mass %, and more preferably 5 to 30 mass %.

When the content falls within the aforementioned range, water absorption properties and a condensation reaction of silanol during heating can be suppressed. Therefore, in formation of a multilayer body, the adherence between a curable resin layer (I) obtained by curing the composition and an inorganic oxide layer (II) can be balanced with the adherence between the curable resin layer (I) and a substrate layer.

### [Compound (B) Having Reactive Group]

The compound (B) having a reactive group that is not the polysiloxane compound (A) (hereinafter sometimes simply referred to as “compound (B)” or “component (B)”) is not particularly limited. Examples thereof include a compound that does not have a silicon atom, a silanol group, a hydrolyzable silyl group, or the like and can be cured by heating or an active energy ray.

In particular, the component (B) is preferably a compound that is not the component (A) among polyfunctional (meth)acrylates having two or more (meth)acryloyl groups in one molecule. In the present invention, “(meth)acrylate” refers to one or both of acrylate and methacrylate, and “(meth)acryloyl group” refers to one or both of acryloyl group and methacryloyl group.

Examples of the polyfunctional (meth)acrylate include di(meth)acrylates of dihydric alcohol such as 1,4-butanediol di(meth)acrylate, 3-methyl-1,5-pentanediol di(meth)acrylate, 1,6-hexanediol di(meth)acrylate, neopentyl glycol di(meth)acrylate, 2-methyl-1,8-octanediol di(meth)acrylate, 2-butyl-2-ethyl-1,3-propanediol di(meth)acrylate, tricyclodecane dimethanol di(meth)acrylate, ethylene glycol di(meth)acrylate, diethylene glycol di(meth)acrylate, triethylene glycol di(meth)acrylate, dipropylene glycol di(meth)acrylate, and tripropylene glycol di(meth)acrylate; polyfunctional (meth)acrylates such as polyethylene glycol di(meth)acrylate, polypropylene glycol di(meth)acrylate, a di(meth)acrylate of tris(2-hydroxyethyl)isocyanurate, a di(meth)acrylate of diol obtained by adding 4 mol or more of ethylene oxide or propylene oxide to 1 mol of neopentylglycol, a di(meth)acrylate of diol obtained by adding 2 mol of ethylene oxide or propylene oxide to 1 mol of bisphenol A, a di(meth)acrylate or tri(meth)acrylate obtained by reacting 1 mol of tris(2-hydroxyethyl) isocyanurate with 2 to 3 mol of acrylic acid, trimethylolpropane tri(meth)acrylate, ethylene oxide-modified trimethylolpropane tri(meth)acrylate, propylene oxide-modified trimethylolpropane tri(meth)acrylate, ditrimethylolpropane tri(meth)acrylate, ditrimethylolpropane tetra(meth)acrylate, tris(2-(meth)acryloyloxyethyl)isocyanurate, glycerol tri(meth)acrylate, pentaerythritol tri(meth)acrylate, pentaerythritol tetra(meth)acrylate, dipentaerythritol tri(meth)acrylate, dipentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, and polypentaerythritol poly(meth)acrylate; and urethane (meth)acrylate obtained by reacting 1 mol of polyisocyanate and two mol or more of (meth)acrylate having a hydroxy group. Urethane acrylate preferably has a cyclic structure. A product obtained by reacting an acrylate containing a hydroxy group with isophorone diisocyanate, methylenebis(4,1-cyclohexylene)=diisocyanate, an isocyanurate product of hexamethylene diisocyanate, an isocyanurate product of isophorone diisocyanate, or an isocyanurate product of methylenebis(4,1-cyclohexylene)=diisocyanate is preferred. The hydroxy group-containing (meth)acrylate to be reacted is preferably pentaerythritol tri(meth)acrylate, 2-hydroxyethyl (meth)acrylate, 2-hydroxypropyl (meth)acrylate, 4-hydroxybutyl (meth)acrylate, or 2-hydroxybutyl (meth)acrylate. Among them, a product obtained by reacting isophorone diisocyanate, an isocyanurate product of hexamethylene diisocyanate, or an isocyanurate product of isophorone diisocyanate with pentaerythritol tri(meth)acrylate, 2-hydroxyethyl (meth)acrylate, or 2-hydroxypropyl (meth)acrylate is preferred.

A monofunctional (meth)acrylate can be used in combination with the polyfunctional (meth)acrylate. Examples of the monofunctional (meth)acrylate include hydroxyl group-containing (meth)acrylates such as hydroxyethyl (meth)acrylate, hydroxypropyl (meth)acrylate, hydroxybutyl (meth)acrylate, caprolactone-modified hydroxy (meth)acrylate (for example, trade name “PLACCEL” available from Daicel Corporation), a mono(meth)acrylate of polyester diol obtained from phthalic acid and propylene glycol, a mono(meth)acrylate of polyester diol obtained from succinic acid and propylene glycol, polyethylene glycol mono(meth)acrylate, polypropylene glycol mono(meth)acrylate, 2-hydroxy-3-(meth)acryloyloxypropyl (meth)acrylate, and (meth)acrylic acid adducts of various types of epoxy esters; carboxyl group-containing vinyl monomers such as (meth)acrylic acid, crotonic acid, itaconic acid, maleic acid, and fumaric acid; sulfonic acid group-containing vinyl monomers such as vinylsulfonic acid, styrenesulfonic acid, and sulfoethyl (meth)acrylate; acidic phosphate-based vinyl monomers such as 2-(meth)acryloyloxyethyl acid phosphate, 2-(meth)acryloyloxypropyl acid phosphate, 2-(meth)acryloyloxy-3-chloro-propyl acid phosphate, and 2-methacryloyloxyethylphenyl phosphoric acid; and vinyl monomers having a methylol group such as N-methylol (meth)acrylamide. One type or two or more types thereof may be used.

As the component (B), a compound having a ring structure in the structure thereof is also preferably used. Due to the presence of the ring structure, degradation of a primer in a humid and hot environment can be suppressed. When a compound having an isocyanurate ring as a ring structure is used, a stress and strain relaxation function can be imparted. This allows interlayer stress and strain that may be generated on an adhesion face between the inorganic oxide layer and the primer layer to be relaxed in a humid and hot environment, and as a result, the adherence can be enhanced. The amount of the compound having an isocyanurate ring in the component (B) is 5 to 100 parts by weight, preferably 10 to 90 parts by weight, and more preferably 20 to 80 parts by weight, relative to 100 parts by weight of the whole amount of the component (B).

The component (B) is preferably a di(meth)acrylate or tri(meth)acrylate obtained by reacting 1 mol of alkylene oxide adduct of isocyanuric acid with 2 to 3 mol of (meth)acrylic acid.

One type of the component (B) may be used, or two or more types thereof may be used in combination. It is preferable that two or more types thereof be used in combination to obtain desired properties.

In particular, as the component (B), at least one type of trifunctional or more (meth)acrylate is preferably used since a high degree of cross-linking is obtained after curing and the hardnesses and permanent adherence of a cured product and a curable resin layer are further enhanced.

The amount of the component (B) blended is preferably 20 to 90 mass %, more preferably 30 to 80 mass %, and further preferably 30 to 70 mass %, relative to the total solid content of the primer composition.

### [Inorganic Oxide Fine Particles (C)]

The inorganic oxide fine particles (C) (hereinafter sometimes referred to as “component (C)”) are not particularly limited as long as they do not impair the effects of the present invention. The inorganic oxide fine particles (C) can be appropriately selected according to a purpose. When a multilayer body is produced using the primer composition of the present invention, it is preferable that inorganic oxide fine particles having high affinity for the inorganic oxide layer or inorganic oxide fine particles formed from the same material as a material for the inorganic oxide layer be selected depending on the material for the inorganic oxide layer layered on the curable resin layer obtained by curing the primer composition.

Examples of the inorganic oxide fine particles (C) that are excellent in thermal conductivity include alumina, titanium oxide, magnesium oxide, zinc oxide, and silicon oxide. Examples of the inorganic oxide fine particles (C) that are excellent in barrier properties include minerals such as mica, clay, kaolin, talc, zeolite, wollastonite, smectite, titanium oxide, and zinc oxide. Examples of the inorganic oxide fine particles (C) that have high refractive index include titanium oxide. Examples of the inorganic oxide fine particles (C) that exhibit photocatalytic properties include oxides of photocatalytic metals such as titanium, cerium, zinc, copper, aluminum, tin, indium, phosphorus, carbon, sulfur, nickel, iron, cobalt, silver, molybdenum, strontium, chromium, barium, and lead. Examples of the inorganic oxide fine particles (C) that are excellent in abrasion resistance include oxides of metals such as silica, alumina, zirconia, and magnesium. Examples of the inorganic oxide fine particles (C) that are excellent in conductivity include tin oxide and indium oxide. Examples of the inorganic oxide fine particles (C) that are excellent in insulating properties include silica. Examples of the inorganic oxide fine particles (C) that are excellent in shielding of ultraviolet light include titanium oxide and zinc oxide.

These inorganic oxide fine particles (C) may be appropriately selected according to use application. The inorganic oxide fine particles may be used alone, or a combination of a plurality of types thereof may be used. Since the inorganic oxide fine particles (C) have various properties other than the properties exemplified, the inorganic oxide fine particles (C) may be appropriately selected according to use application.

For example, when silica is used as the inorganic oxide fine particles (C), publicly known silica fine particles such as powdered silica or colloidal silica can be used without particular limitation. Examples of commercially available powdered silica fine particles include AEROSIL 50 and 200 available from NIPPON AEROSIL CO., LTD., Sildex H31, H32, H51, H52, H121, and H122 available from Asahi Glass Co., Ltd., E220A and E220 available from Nippon Silica Industrial Co., Ltd., SYLYSIA470 available from FUJI SILYSIA CHEMICAL LTD., and SG flake available from Nippon Sheet Glass Co., Ltd.

Examples of commercially available colloidal silica include methanol silica sol, IPA-ST, IPA-ST-L, IPA-ST-ZL, PGM-ST, PGM-ST-UP, NBA-ST, XBA-ST, DMAC-ST, ST-UP, ST-OUP, ST-20, ST-40, ST-C, ST-N, ST-O, ST-50, and ST-OL available from Nissan Chemical Corporation.

Surface-modified silica fine particles may be used. Examples thereof include those surface-treated with a reactive silane coupling agent having a hydrophobic group and those modified with a compound having a (meth)acryloyl group. Examples of commercially available powdered silica modified with a compound having a (meth)acryloyl group include AEROSIL RM50, R7200, and R711 available from NIPPON AEROSIL CO., LTD. Examples of commercially available colloidal silica modified with a compound having a (meth)acryloyl group include MIBK-SD, MEK-SD, MEK-AC-2140Z, MEK-AC-4130Y, MEK-AC-5140Z, PGM-AC-2140Z, and MIBK-AC-2140Z available from Nissan Chemical Corporation. Examples of colloidal silica surface-treated with a reactive silane coupling agent having a hydrophobic group include MIBK-ST and MEK-ST available from Nissan Chemical Corporation.

The shape of the silica fine particles is not particularly limited. Spherical, hollow, porous, rod-shaped, plate-shaped, fibrous, or amorphous silica fine particles can be used. For example, as commercially available hollow silica fine particles, SiliNax available from Nittetsu Mining Co., Ltd., or the like can be used.

As titanium oxide fine particles, not only an extender pigment but also ultraviolet light-responsive photocatalyst can be used. For example, anatase-type titanium oxide, rutile-type titanium oxide, brookite-type titanium oxide, or the like can be used. In addition, particles that are designed to respond to visible light by doping a crystal structure of titanium oxide with a heterologous element can be used. As an element with which titanium oxide is doped, an anionic element such as nitrogen, sulfur, carbon, fluorine, or phosphorus, or a cationic element such as chromium, iron, cobalt, or manganese is suitably used. As the state of titanium oxide, a powder, or a sol or a slurry in which titanium oxide is dispersed in an organic solvent or water can be used. Examples of commercially available powdered titanium oxide fine particles include AEROSIL P-25 available from NIPPON AEROSIL CO., LTD., or ATM-100 available from Tayca Co., Ltd. Examples of commercially available titanium oxide fine particles in a slurry state include TKD-701 available from Tayca Co., Ltd.

The average particle diameter of the component (C) of the present invention in the composition is preferably within the range of 5 to 200 nm. When the average particle diameter is 5 nm or more, dispersibility is favorable. When the average particle diameter is 200 nm or less, the strength of a cured product or a curable resin layer is high. The average particle diameter is more preferably 10 nm to 100 nm, further preferably 10 nm to 80 nm, particularly preferably 10 nm to 50 nm, and the most preferably 10 nm to 30 nm. The “average particle diameter” used herein is measured with a particle size distribution analyzer or the like using a dynamic light scattering method.

The amount of the component (C) blended is preferably 70 mass % or less, more preferably 0.1 to 60 mass %, further preferably 3 to 50 mass %, particularly preferably 5 to 50 mass %, and the most preferably 25 to 45 mass %, relative to the total solid content of the primer composition.

The ratio by mass (A)/(C) of the solid content of the component (A) to the solid content of the component (C) is preferably 10/90 to 80/20, more preferably 20/80 to 70/30, and further preferably 40/60 to 50/50.

The component (C) alone may be blended in the composition of the present invention, or the component (C) that is bonded to another component may be blended in the composition.

In particular, an inorganic fine particle composite (D) is preferably formed by bonding the component (C) to the component (A). When the component (C) is strongly bonded to the component (A), segregation, phase separation, detachment, and the like of the component (C) in a curable resin layer after curing are suppressed, and as a result, excellent interlayer adherence is achieved even in a humid and hot environment. Therefore, the resultant product can be suitably used for a building material used outside and an automotive member.

When the component (C) is bonded to the component (A), the components are preferably bonded to each other through a siloxane bond. In this case, the component (C) that has a functional group capable of forming a siloxane bond with the component (A) is preferably used.

The functional group capable of forming a siloxane bond may be any group as long as it is a functional group capable of forming a siloxane bond, such as a hydroxy group, a silanol group, and an alkoxysilyl group. The inorganic oxide fine particles themselves capable of forming a siloxane bond may have the functional group, or the inorganic oxide fine particles may be modified to introduce the functional group.

As a method for modifying the inorganic oxide fine particles, a publicly known and commonly used method may be used. Examples thereof include methods such as treatment with a silane coupling agent and coating with a resin having the functional group capable of forming a siloxane bond.

In addition to the component (C) bonded to the component (A), alumina, magnesia, titania, zirconia, silica, or the like may be separately blended as the component (C) that is not bonded.

When as the component (C), for example, silica is simply blended in a resin to obtain a curable resin layer, a coating film may be corroded from a silica portion by moisture and deteriorated due to hydrophilicity of the silica. However, strong bonding of the component (C) to the component (A) can prevent such a problem.

### (Method for Producing Inorganic Fine Particle Composite (D))

The inorganic fine particle composite (D) can be produced, for example, by a method in which a monomer for the component (A) is mixed with the component (C) and a condensation reaction for the component (A) and a reaction for bonding the component (C) to the component (A) are simultaneously performed; a method in which the component (A) is obtained by a condensation reaction using a raw material monomer for the component (A), the component (C) is then added, and a reaction for bonding the component (C) to the component (A) is performed, or the like.

Specific examples of the raw material monomer for the component (A) include vinyltrimethoxysilane, vinyltriethoxysilane, vinylmethyldimethoxysilane, vinyltris(2-methoxyethoxy)silane, vinyltriacetoxysilane, vinyltrichlorosilane, 2-trimethoxysilyl ethyl vinyl ether, 3-(meth)acryloyloxypropyltrimethoxysilane, 3-(meth)acryloyloxypropyltriethoxysilane, 3-(meth)acryloyloxypropylmethyldimethoxysilane, and 3-(meth)acryloyloxypropyltrichlorosilane. Among them, vinyltrimethoxysilane and 3-(meth)acryloyloxypropyltrimethoxysilane are preferred since a hydrolysis reaction can be easily promoted and a by-product after the reaction can be easily removed.

With the raw material monomer for the component (A), a general-purpose silane compound can be used. Examples of the general-purpose silane compound include various organotrialkoxysilanes such as methyltrimethoxysilane, methyltriethoxysilane, methyltri-n-butoxysilane, ethyltrimethoxysilane, n-propyltrimethoxysilane, iso-butyltrimethoxysilane, cyclohexyltrimethoxysilane, phenyltrimethoxysilane, and phenyltriethoxysilane; various diorganodialkoxysilanes such as dimethyldimethoxysilane, dimethyldiethoxysilane, dimethyldi-n-butoxysilane, diethyldimethoxysilane, diphenyldimethoxysilane, methylcyclohexyldimethoxysilane, and methylphenyldimethoxysilane; and chlorosilanes such as methyltrichlorosilane, ethyltrichlorosilane, phenyltrichlorosilane, vinyltrichlorosilane, dimethyldichlorosilane, diethyldichlorosilane, and diphenyldichlorosilane. Among them, organotrialkoxysilane and diorganodialkoxysilane are preferred since a hydrolysis reaction can be easily promoted and a by-product after the reaction can be easily removed.

Further, a tetrafunctional alkoxysilane compound such as tetramethoxysilane, tetraethoxysilane, or tetra-n-propoxysilane, or a partial hydrolytic condensate of the tetrafunctional alkoxysilane compound can be used within a range that does not impair the effects of the present invention. When the tetrafunctional alkoxysilane compound or the partial hydrolytic condensate thereof is used, it is preferable that the amount of silicon atom of the tetrafunctional alkoxysilane compound do not exceed 20 mol % relative to the total amount of silicon atoms of the raw material monomer for the component (A).

As the raw material monomer for the component (A), a metal alkoxide compound in which the metal is a metal other than a silicon atom, such as boron, titanium, zirconium, or aluminum can be used within a range that does not impair the effects of the present invention. For example, the metal alkoxide compound is preferably used such that the metal atom of the metal alkoxide compound described above does not exceed 25 mol % relative to the total amount of silicon atoms of the raw material monomer for the component (A)

In order to introduce the group represented by the formula (3) into the component (A), a silane compound having the group represented by the formula (3) may be used. Specific examples of the silane compound having the group represented by the formula (3) include p-styryltrimethoxysilane and p-styryltriethoxysilane.

To mix the component (A) or the raw material monomer for the component (A) with the component (C), a publicly known dispersion method can be used. Examples of mechanical means include a disperser, a dispersion machine having a stirrer blade such as a turbine blade, a paint shaker, a roll mill, a ball mill, Attritor, a sand mill, and a bead mill. For uniform mixing, dispersion with a bead mill using a dispersion media such as glass beads and zirconia beads is preferred.

Examples of the bead mill include Star Mil manufactured by Ashizawa Finetech Ltd.; MSC-MILL, SC-MILL, and Attritor MA01SC manufactured by Mitsui Mining Co., Ltd.; nano grain mill, pico mill, pure grain mill, megacaper grain mill, cera power grain mill, dual grain mill, AD mill, twin AD mill, basket mill, and twin basket mill manufactured by Asada Iron Works Co., Ltd.; and apex mill, ultra apex mill, and super apex mill manufactured by Kotobuki Industries Co., Ltd.

In order to prepare the solid content and the viscosity, a dispersion medium may be used during mixing or the reaction. The dispersion medium is not limited as long as it is a liquid dispersion medium that does not impair the effects of the present invention. Examples thereof include various organic solvents, water, and liquid organic polymers and monomers.

Examples of the organic solvent include ketones such as acetone, methyl ethyl ketone (MEK), and methyl isobutyl ketone (MIBK), cyclic ethers such as tetrahydrofuran (THF) and dioxolane, esters such as methyl acetate, ethyl acetate, and butyl acetate, aromatic compounds such as toluene and xylene, alcohols such as carbitol, cellosolve, methanol, isopropanol (2-propanol), butanol, propylene glycol monomethyl ether, and n-propyl alcohol. The organic solvents may be used alone or in combination.

A hydrolysis-condensation reaction refers to a condensation reaction that proceeds between hydroxy groups that are formed by hydrolysis of a part of the hydrolyzable group due to influence of water or the like or between the hydroxy groups and the hydrolyzable group. The hydrolysis-condensation reaction can be promoted by a publicly known method. A method for promoting the reaction by supplying water and a catalyst in the production process described above is simple and preferred.

Examples of a used catalyst include inorganic acids such as hydrochloric acid, sulfuric acid, and phosphoric acid; organic acids such as p-toluenesulfonic acid, monoisopropyl phosphate, and acetic acid; inorganic bases such as sodium hydroxide and potassium hydroxide; titanates such as tetraisopropyl titanate and tetrabutyl titanate; various compounds containing a basic nitrogen atom, such as 1,8-diazabicyclo[5.4.0]undecene-7 (DBU), 1,5-diazabicyclo[4.3.0]nonene-5 (DBN), 1,4-diazabicyclo[2.2.2]octane (DABCO), tri-n-butylamine, dimethylbenzylamine, monoethanolamine, imidazole, and 1-methylimidazole; various quaternary ammonium salts such as a tetramethyl ammonium salt, a tetrabutyl ammonium salt, a dilauryldimethyl ammonium salt, and quaternary ammonium salts having as a counter anion chloride, bromide, carboxylate, or hydroxide; tin carboxylates such as dibutyltin diacetate, dibutyltin dioctoate, dibutyltin dilaurate, dibutyltin diacetylacetonate, tin octylate, and tin stearate. The catalyst may be used alone, or two or more types thereof may be used in combination.

The amount of the catalyst added is not particularly limited. Generally, the catalyst is used preferably in an amount falling within the range of 0.0001 to 10 mass %, more preferably 0.0005 to 3 mass %, and particularly preferably 0.001 to 1 mass % relative to the total amount of the compounds having the silanol group or the hydrolyzable silyl group.

The amount of water supplied is preferably 0.05 mol or more, more preferably 0.1 mol or more, and particularly preferably 0.5 mol or more per mole of the silanol group or the hydrolyzable silyl group of each of the compounds having the silanol group or the hydrolyzable silyl group.

The catalyst and water may be supplied at once or sequentially, or the catalyst and water may be mixed in advance and supplied.

The reaction temperature during the hydrolysis-condensation reaction is appropriately within the range of 0° C. to 150° C., and preferably within the range of 20° C. to 100° C. The reaction can be performed under a condition where the pressure of the reaction is any of normal pressure, increased pressure, or reduced pressure. An alcohol and water that are by-products that may be produced in the hydrolysis-condensation reaction may be removed by a method such as distillation, if necessary.

### (Optional Component)

In addition to the components (A) to (D), the primer composition of the present invention may contain another component within the range that does not impair the effects of the present invention.

As the other component, a variety of additives, such as a photopolymerization initiator, a photostabilizer, an ultraviolet absorber, a curing agent for curing an epoxy group, a curing accelerator, a catalyst, an organic solvent, a leveling agent, an inorganic pigment, an organic pigment, an extender pigment, a clay mineral, a wax, a surfactant, a stabilizer, a flowing adjuster, a dye, a rheology controller, an anti-foaming agent, an antioxidant, or a plasticizer can be used.

As a photopolymerization initiator, one publicly known to be a photo-radical polymerization initiator, a photo-cationic polymerization initiator, or a photo-anionic polymerization initiator may be used. For example, one or more selected from the group consisting of acetophenones, benzyl ketals, and benzophenones can be preferably used. Examples of the acetophenones include diethoxy acetophenone, 2-hydroxy-2-methyl-1-phenylpropan-1-one, 1-(4-isopropylphenyl)-2-hydroxy-2-methylpropan-1-one, and 4-(2-hydroxyethoxy)-phenyl-(2-hydroxy-2-propyl) ketone. Examples of the benzyl ketals include 1-hydroxycyclohexyl phenyl ketone and benzyl dimethyl ketal. Examples of the benzophenones include benzophenone and methyl o-benzoylbenzoate. Examples of the benzoins include benzoin, benzoin methyl ether, and benzoin isopropyl ether. The photopolymerization initiator may be used alone, or two or more types thereof may be used in combination.

When the primer composition of the present invention is cured by an active energy ray, the photopolymerization initiator is preferably used.

The amount of the photopolymerization initiator used is preferably 1 to 15 mass %, and more preferably 2 to 10 mass %, relative to 100 mass % of the solid content of the primer composition.

Examples of the light stabilizer include a hindered amine light stabilizer (HALS). Various light stabilizers can be used. Examples thereof include bis(2,2,6,6-tetramethyl-4-piperidyl) sebacate, bis(1,2,2,6,6-pentamethyl-4-piperidyl) sebacate, bis(1-octoxy-2,2,6,6-tetramethyl-4-piperidyl) sebacate, bis(1-methoxy-2,2,6,6-tetramethyl-4-piperidyl) sebacate, dimethyl succinate-1-(2-hydroxyethyl)-4-hydroxy-2,2,6,6-tetramethylpiperidine polymer, poly[{6-(1,1,3,3-tetramethylbutyl)imino-1,3,5-triazine-2,4-diyl}{(2,2,6,6-tetramethyl-4-piperidyl)imino}hexamethylene {(2,2,6,6-tetramethyl-4-piperidyl)imino}], 1-[2-{3-(3,5-di-t-butyl-4-hydroxyphenyl)propionyloxy}ethyl]-4-{3-(3,5-di-t-butyl-4-hydroxyphenyl)propionyloxy}-2,2,6,6-tetramethylpiperidine, 3-dodecyl-1-(2,2,6,6-tetramethyl-4-piperidyl)pyrrolidine-2,5-dione, and N-methyl-3-dodecyl-1-(2,2,6,6-tetramethyl-4-piperidyl)pyrrolidine-2,5-dione.

As an ultraviolet absorber, for example, various inorganic or organic ultraviolet absorbers generally used can be used. Examples of the ultraviolet absorber include compound derivatives having a hydroxybenzophenone, benzotriazole, cyanoacrylate, or triazine main skeleton, and polymers such as a vinyl polymer containing the ultraviolet absorber incorporated on a side chain. Specific examples thereof include 2,4′-dihydroxybenzophenone, 2,2′,4,4′-tetrahydroxybenzophenone, 2-hydroxy-4-methoxybenzophenone, 2-hydroxy-4-methoxybenzophenone-5-sulfonic acid, 2-hydroxy-4-n-octoxybenzophenone, 2-hydroxy-4-n-dodecyloxybenzophenone, 2-hydroxy-4-n-benzyloxybenzophenone, 2,2′-dihydroxy-4,4′-dimethoxybenzophenone, 2,2′-dihydroxy-4,4′-diethoxybenzophenone, 2,2′-dihydroxy-4,4′-dipropoxybenzophenone, 2,2′-dihydroxy-4,4′-dibutoxybenzophenone, 2,2′-dihydroxy-4-methoxy-4′-propoxybenzophenone, 2,2′-dihydroxy-4-methoxy-4′-butoxybenzophenone, 2,3,4-trihydroxybenzophenone, 2-(2-hydroxy-5-t-methylphenyl)benzotriazole, 2-(2-hydroxy-5-t-octylphenyl)benzotriazole, 2-(2-hydroxy-3,5-di-t-butylphenyl)benzotriazole, ethyl-2-cyano-3,3-diphenyl acrylate, 2-ethylhexyl-2-cyano-3,3-diphenyl acrylate, 2-(2-hydroxy-4-hexyloxyphenyl)-4,6-diphenyltriazine, 4-(2-acryloxyethoxy)-2-hydroxybenzophenone polymers, and 2-(2′-hydroxy-5′-methacryloxyethylphenyl)-2H-benzotriazole polymers. Among them, 2,2′,4,4′-tetrahydroxybenzophenone is suitably used in terms of vaporization. Two or more types of the organic ultraviolet absorbers may be used in combination.

When the composition containing the ultraviolet absorber is used, a cured product and a curable resin layer can suppress yellowing of a substrate formed from plastics or the like. Consequently, the adherence between the substrate and the curable resin layer is enhanced, and the light resistance is improved.

When the component (A) contains an epoxy group, a publicly known curing agent for epoxy resin can be used. Examples thereof include phenolic compounds such as a phenol novolac resin, a cresol novolac resin, an aromatic hydrocarbon formaldehyde resin-modified phenolic resin, a dicyclopentadiene phenol-added resin, a phenolaralkyl resin (zylock resin), a naphthol aralkyl resin, a trimethylolmethane resin, a tetraphenylolethane resin, a naphthol novolac resin, a naphthol-phenol co-condensed novolac resin, a naphthol-cresol co-condensed novolac resin, a biphenyl-modified phenolic resin (a polyhydric phenol compound having a phenolic nucleus linked through a bismethylene group), a biphenyl-modified naphthol resin (a polyhydric naphthol compound having a phenolic nucleus linked through a bismethylene group), an aminotriazine-modified phenolic resin (a polyhydric phenol compound having a phenolic nucleus linked through melamine, benzoguanamine, or the like), and an alkoxy group-containing aromatic ring-modified novolac resin (a polyhydric phenol compound in which a phenolic nucleus and an alkoxy group-containing aromatic ring are linked through formaldehyde); acid anhydride-based compounds such as phthalic anhydride, trimellitic anhydride, pyromellitic anhydride, maleic anhydride, tetrahydrophthalic anhydride, methyltetrahydrophthalic anhydride, methyl nadic anhydride, hexahydrophthalic anhydride, and methylhexahydrophthalic anhydride; amide compounds such as dicyandiamide and a polyamide resin synthesized from a dimer of linolenic acid and ethylenediamine; and amine compounds such as diaminodiphenylmethane, diethylenetriamine, triethylenetetramine, diaminodiphenyl sulfone, isophoronediamine, imidazole, a BF3-amine complex, and a guanidine derivative.

As a curing accelerator, various compounds can be used. Examples thereof include a phosphorus-containing compound, a tertiary amine, imidazole, an organic acid metal salt, a Lewis acid, and an amine complex salt. 2-ethyl-4-methylimidazole as an imidazole compound, triphenyl phosphine as a phosphorus-containing compound, and 1,8-diazabicyclo-[5.4.0]-undecene (DBU) as a tertiary amine are preferred since they are particularly excellent in curability, heat resistance, electrical characteristics, moisture-resistant reliability, and the like.

In the case of using combination of curing by an active energy ray and thermal curing, it is preferable that each catalyst be selected in consideration of a reaction of a polymerizable double bond in the composition, and the reaction temperature, reaction time, and the like of a thermosetting reaction group. A thermosetting resin can be used in combination. Examples of the thermosetting resin include a vinyl-based resin, an unsaturated polyester resin, a polyurethane resin, an epoxy resin, an epoxy ester resin, an acrylic resin, a phenol resin, a petroleum resin, a ketone resin, a silicone resin, and modified resins thereof.

In order to adjust the viscosity, the primer composition of the present invention may contain an organic solvent. As the organic solvent, for example, an aliphatic or alicyclic hydrocarbon such as n-hexane, n-heptane, n-octane, cyclohexane, or cyclopentane; an aromatic hydrocarbon such as toluene, xylene, or ethylbenzene; an alcohol such as methanol, ethanol, n-butanol, ethylene glycol monomethyl ether, or propylene glycol monomethyl ether; an ester such as ethyl acetate, butyl acetate, n-butyl acetate, n-amyl acetate, ethylene glycol monomethyl ether acetate, or propylene glycol monomethyl ether acetate; a ketone such as acetone, methyl ethyl ketone, methyl isobutyl ketone, methyl n-amyl ketone, or cyclohexanone; a polyalkylene glycol dialkyl ether such as diethylene glycol dimethyl ether or diethylene glycol dibutyl ether; an ether such as 1,2-dimethoxyethane, tetrahydrofuran, or dioxane; N-methylpyrrolidone, dimethylformamide, dimethylacetamide, or ethylene carbonate may be used alone, or two or more types thereof may be used in combination.

A leveling agent is a liquid organic polymer that does not contribute directly to a curing reaction. Examples thereof include a carboxyl group-containing polymer modified product (FLOWLEN G-900, NC-500: Kyoeisha Chemical Co., Ltd.), an acrylic polymer (FLOWLEN WK-20: Kyoeisha Chemical Co., Ltd.), an amine salt of specialized modified phosphate (HIPLAAD ED-251: Kusumoto Chemicals, Ltd.), and a modified acrylic block copolymer (DISPERBYK2000: BYK).

Examples of the silane coupling agent include silane compounds having a silanol group and/or a hydrolyzable silyl group except for one corresponding to the component (A).

Specific examples thereof include publicly known and commonly used silane compounds including: various organotrialkoxysilanes such as methyltrimethoxysilane, methyltriethoxysilane, methyltri-n-butoxysilane, ethyltrimethoxysilane, n-propyltrimethoxysilane, iso-butyltrimethoxysilane, cyclohexyltrimethoxysilane, tris(trimethoxysilylpropyl) isocyanurate, 3-aminopropyltrimethoxysilane, and 3-aminopropyltriethoxysilane; various diorganodialkoxysilanes such as dimethyldimethoxysilane, dimethyldiethoxysilane, dimethyldi-n-butoxysilane, diethyldimethoxysilane, and methylcyclohexyldimethoxysilane; and chlorosilanes such as methyltrichlorosilane, ethyltrichlorosilane, vinyltrichlorosilane, dimethyldichlorosilane, and diethyldichlorosilane. Among them, from the viewpoint of hardness and compatibility with an organic resin, tris(trimethoxysilylpropyl) isocyanurate is desired.

### <Cured Product>

The primer composition of the present invention can be cured by an active energy ray, heating, or the like.

Examples of the active energy ray include ultraviolet light emitted from a light source such as a xenon lamp, a low-pressure mercury lamp, a high-pressure mercury lamp, an ultra-high pressure mercury lamp, a metal halide lamp, a carbon arc lamp, or a tungsten lamp, and an electron beam, an α ray, a β ray, and a γ ray usually obtained from a particle accelerator of 20 to 2,000 kV. Among them, ultraviolet light or an electron beam is preferably used. In particular, ultraviolet light is suitable. As an ultraviolet light source, a sunlight ray, a low-pressure mercury lamp, a high-pressure mercury lamp, an ultra-high pressure mercury lamp, a carbon arc lamp, a metal halide lamp, a xenon lamp, an argon laser, a helium/cadmium laser, or the like can be used. By using them, a coated surface of the active energy ray-curable resin layer is irradiated with ultraviolet light having a wavelength of about 180 to 400 nm, a coating film can be cured. The irradiation dose of ultraviolet light is appropriately selected depending on the type and the amount of the photopolymerization initiator used. The coating film can be cured also by using a heat of about 25 to 150° C. or in combination with curing with an active energy ray within a range that does not affect the cured product and the composition. In this case, as a heating source, a publicly known heat source such as hot air and a near infrared ray is applicable.

### <Multilayer Body>

A multilayer body of the present invention has the curable resin layer (I) and the inorganic oxide layer (II) containing an inorganic oxide. It is preferable that the multilayer body further have a substrate layer and on the substrate, the curable resin layer (I) and the inorganic oxide layer (II) in this order be layered.

Hereinafter, the layers will be each described.

### [Curable Resin Layer (I)]

The curable resin layer (I) is obtained by curing the primer composition of the present invention.

A method for producing the curable resin layer (I) is not particularly limited, and the primer composition can be applied to a substrate and cured, to form the curable resin layer (I) For example, a coating liquid of the primer composition may be applied to a substrate described later, or a layer obtained by applying the primer composition to a surface formed from another material different from the substrate, such as plastic, metal, or glass may be used as the curable resin layer (I). When the multilayer body of the present invention has no substrate, the curable resin layer (I) may be peeled from the substrate or the other material different from the substrate after application and curing.

An applying method is not particularly limited. A publicly known method such as a spraying method, a spin coating method, a dip method, a roll-coating method, a blade coating method, a doctor roll method, a doctor blade method, a curtain coating method, a slit coating method, a screen printing method, or an inkjet method can be used.

A curing method is as described in the description of <Cured Product>.

From the viewpoint of forming a multilayer body having adherence, the curable resin layer (I) preferably has a thickness of 1 to 50 μm. When the thickness is 1 μm or more, an effect of adherence to the substrate, which is present, is high. When the thickness is 50 μm or less, sufficient curing is achieved, and the adherence between the curable resin layer (I) and the inorganic oxide layer (II) is high. In terms of adherence, the thickness is preferably 1 nm to 30 μm, and particularly preferably 100 nm to 10 μm.

The surface roughness (Ra) of the curable resin layer (I) is preferably less than 2.0 nm, more preferably 1.5 nm or less, and further preferably 1.0 nm or less.

When Ra is equal to or less than the upper limit value, excessive unevenness is formed on the surface of the curable resin layer (I), the fragility of the uneven portion is not increased, and as a result, breaking between the layers of the multilayer body and a decrease in adherence can be prevented. The multilayer body of the present invention has the curable resin layer (I) using a specific amount of the component (A) having a specific structure. Therefore, although Ra is a relatively low value, sufficient adherence between the curable resin layer (I) and the inorganic oxide layer (II) and sufficient adherence between the curable resin layer (I) and the substrate layer are achieved, and the adherences can be balanced with each other. The surface roughness can be measured by a publicly known and commonly used method.

### [Inorganic Oxide Layer (II)]

The inorganic oxide layer (II) of the present invention is a layer that is layered on the curable resin layer (I). A material is not particularly limited, and a layering method is not particularly limited. The material and the layering method may be appropriately selected depending on the application of the multilayer body. The inorganic oxide layer (II) may be formed from a single material, or may be formed from a plurality of materials. The inorganic oxide layer (II) may have a single-layer structure in which a single layer is layered or a multilayer structure in which a plurality of layers are layered. The inorganic oxide layer (II) may be formed from a portion of a different material of the curable resin layer (I).

Examples of the inorganic oxide constituting the inorganic oxide layer (II) include silicon oxide, aluminum oxide, titanium oxide, zirconium oxide, and zinc oxide. One type of the inorganic oxide may be used, or a plurality of types thereof may be used simultaneously.

Since the hardness of the inorganic oxide layer is very high, the inorganic oxide layer can be favorably used as a hardcoat film. The inorganic oxide layer can be used particularly to protect plastic, rubber, and the like that are frangible. Since the refractive index is easily controlled, an optical function such as antireflection can be imparted. The inorganic oxide layer can be used as a substrate for an electronic material. Since the inorganic oxide layer is further excellent in gas barrier properties, the inorganic oxide layer can be used for various packing materials, fuel cell members, organic thin film solar cell members, and the like.

When the inorganic oxide layer (II) is formed by an applying method, a coating liquid of the inorganic oxide is applied and cured to form the inorganic oxide layer (II). For example, the coating liquid of the inorganic oxide may be applied to the curable resin layer (I), or a layer obtained by applying the inorganic oxide to a surface formed from another material, such as plastic, metal, or glass may be used as the inorganic oxide layer (II).

Examples of the applying method include, but not particularly limited, a spraying method, a spin coating method, a dip method, a roll-coating method, a blade coating method, a doctor roll method, a doctor blade method, a curtain coating method, a slit coating method, a screen printing method, and an inkjet method.

A material for the coating liquid of the inorganic oxide may be particles of the inorganic oxide, a metal alkoxide compound that forms the inorganic oxide under hydrolysis, or a hydrolysis-condensate thereof. In the case of the metal alkoxide compound, a curable organopolysiloxane is particularly preferred, and an example is a coating liquid that is cured thermally or by an active energy ray such as an electron beam or ultraviolet light. When the curable organopolysiloxane is three-dimensionally cross-linked, the cross-linking density is increased, and an organopolysiloxane cured product layer that is the inorganic oxide layer having high abrasion resistance is obtained.

Examples of the metal alkoxide compound or the hydrolysis-condensate thereof include a silane compound using a silanol group and/or a hydrolyzable silyl group in combination and a hydrolysis-condensate thereof. Specific examples thereof include publicly known and commonly used silane compounds including: various organotrialkoxysilanes such as methyltrimethoxysilane, methyltriethoxysilane, methyltri-n-butoxysilane, ethyltrimethoxysilane, n-propyltrimethoxysilane, iso-butyltrimethoxysilane, and cyclohexyltrimethoxysilane; various diorganodialkoxysilanes such as dimethyldimethoxysilane, dimethyldiethoxysilane, dimethyldi-n-butoxysilane, diethyldimethoxysilane, and methylcyclohexyldimethoxysilane; and chlorosilanes such as methyltrichlorosilane, ethyltrichlorosilane, vinyltrichlorosilane, dimethyldichlorosilane, and diethyldichlorosilane. Among them, organotrialkoxysilane and diorganodialkoxysilane are preferred since a hydrolysis reaction can be easily promoted and a by-product after the reaction can be easily removed.

A silane compound having a functional group other than the silanol group and/or the hydrolyzable silyl group may be used. Examples of the functional group other than the silanol group and/or the hydrolyzable silyl group include a group having a polymerizable double bond, and an epoxy group.

For example, as a silane compound having a polymerizable double bond, vinyltrimethoxysilane, vinyltriethoxysilane, vinylmethyldimethoxysilane, vinyltris(2-methoxyethoxy)silane, vinyltriacetoxysilane, vinyltrichlorosilane, 2-trimethoxysilyl ethyl vinyl ether, 3-(meth)acryloyloxypropyltrimethoxysilane, 3-(meth)acryloyloxypropyltriethoxysilane, 3-(meth)acryloyloxypropylmethyldimethoxysilane, 3-(meth)acryloyloxypropyltrichlorosilane, and the like are used in combination. Among them, vinyltrimethoxysilane and 3-(meth)acryloyloxypropyltrimethoxysilane are preferred since a hydrolysis reaction can be easily promoted and a by-product after the reaction can be easily removed.

Examples of an epoxy group-containing silane compound include γ-glycidoxypropyltrimethoxysilane, γ-glycidoxypropyltriethoxysilane, γ-glycidoxypropyltrimethoxyethoxysilane, γ-glycidoxypropyltriacetoxysilane, β-(3,4-epoxycyclohexyl)ethyltrimethoxysilane, β-(3,4-epoxycyclohexyl)ethyltriethoxysilane, β-(3,4-epoxycyclohexyl)ethyltrimethoxyethoxysilane, β-(3,4-epoxycyclohexyl)ethyltriacetoxysilane, γ-glycidoxypropyldimethoxymethylsilane, γ-glycidoxypropyldiethoxymethylsilane, γ-glycidoxypropyldimethoxyethoxymethylsilane, γ-glycidoxypropyldiacetoxymethylsilane, β-(3,4-epoxycyclohexyl)ethyldimethoxymethylsilane, β-(3,4-epoxycyclohexyl)ethyldiethoxymethylsilane, β-(3,4-epoxycyclohexyl)ethyldimethoxyethoxymethylsilane, β-(3,4-epoxycyclohexyl)ethyldiacetoxymethylsilane, γ-glycidoxypropyldimethoxyethylsilane, γ-glycidoxypropyldiethoxyethylsilane, γ-glycidoxypropyldimethoxyethoxyethylsilane, γ-glycidoxypropyldiacetoxyethylsilane, β-(3,4-epoxycyclohexyl)ethyldimethoxyethylsilane, β-(3,4-epoxycyclohexyl)ethyldiethoxyethylsilane, β-(3,4-epoxycyclohexyl)ethyldimethoxyethoxyethylsilane, β-(3,4-epoxycyclohexyl)ethyldiacetoxyethylsilane, γ-glycidoxypropyldimethoxyisopropylsilane, γ-glycidoxypropyldiethoxyisopropylsilane, γ-glycidoxypropyldimethoxyethoxyisopropylsilane, γ-glycidoxypropyldiacetoxyisopropylsilane, β-(3,4-epoxycyclohexyl)ethyldiethoxyisopropylsilane, β-(3,4-epoxycyclohexyl)ethyldiethoxyisopropylsilane, β-(3,4-epoxycyclohexyl)ethyldimethoxyethoxyisopropylsilane, β-(3,4-epoxycyclohexyl)ethyldiacetoxyisopropylsilane, γ-glycidoxypropylmethoxydimethylsilane, γ-glycidoxypropylethoxydimethylsilane, γ-glycidoxypropylmethoxyethoxydimethylsilane, γ-glycidoxypropylacetoxydimethylsilane, β-(3,4-epoxycyclohexyl)ethylmethoxydimethylsilane, β-(3,4-epoxycyclohexyl)ethylethoxydimethylsilane, β-(3,4-epoxycyclohexyl)ethylmethoxyethoxydimethylsilane, β-(3,4-epoxycyclohexyl)ethylacetoxydimethylsilane, γ-glycidoxypropylmethoxydiethylsilane, γ-glycidoxypropylethoxydiethylsilane, γ-glycidoxypropylmethoxyethoxydiethylsilane, γ-glycidoxypropylacetoxydiethylsilane, β-(3,4-epoxycyclohexyl)ethylmethoxydiethylsilane, β-(3,4-epoxycyclohexyl)ethylethoxydiethylsilane, β-(3,4-epoxycyclohexyl)ethylmethoxyethoxydiethylsilane, β-(3,4-epoxycyclohexyl)ethylacetoxydiethylsilane, γ-glycidoxypropylmethoxydiisopropylsilane, γ-glycidoxypropylethoxydiisopropylsilane, γ-glycidoxypropylmethoxyethoxydiisopropylsilane, γ-glycidoxypropylacetoxydiisopropylsilane, β-(3,4-epoxycyclohexyl)ethylmethoxydiisopropylsilane, β-(3,4-epoxycyclohexyl)ethylethoxydiisopropylsilane, β-(3,4-epoxycyclohexyl)ethylmethoxyethoxydiisopropylsilane, β-(3,4-epoxycyclohexyl)ethylacetyoxydiisopropylsilane, γ-glycidoxypropylmethoxyethoxymethylsilane, γ-glycidoxypropylacetoxymethoxymethylsilane, γ-glycidoxypropylacetoxyethoxymethylsilane, β-(3,4-epoxycyclohexyl)ethylmethoxyethoxymethylsilane, β-(3,4-epoxycyclohexyl)ethylmethoxyacetoxymethylsilane, β-(3,4-epoxycyclohexyl)ethylethoxyacetoxymethylsilane, γ-glycidoxypropylmethoxyethoxyethylsilane, γ-glycidoxypropylacetoxymethoxyethylsilane, γ-glycidoxypropylacetoxyethoxyethylsilane, β-(3,4-epoxycyclohexyl)ethylmethoxyethoxyethylsilane, β-(3,4-epoxycyclohexyl)ethylmethoxyacetoxyethylsilane, β-(3,4-epoxycyclohexyl)ethylethoxyacetoxyethylsilane, γ-glycidoxypropylmethoxyethoxyisopropylsilane, γ-glycidoxypropylacetoxymethoxyisopropylsilane, γ-glycidoxypropylacetoxyethoxyisopropylsilane, β-(3,4-epoxycyclohexyl)ethylmethoxyethoxyisopropylsilane, β-(3,4-epoxycyclohexyl)ethylmethoxyacetoxyisopropylsilane, β-(3,4-epoxycyclohexyl)ethylethoxyacetoxyisopropylsilane, glycidoxymethyltrimethoxysilane, glycidoxymethyltriethoxysilane, α-glycidoxyethyltrimethoxysilane, α-glycidoxymethyltrimethoxysilane, β-glycidoxyethyltrimethoxysilane, β-glycidoxymethyltrimethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltrimethoxysilane, β-glycidoxybutyltriethoxysilane, γ-glycidoxybutyltrimethoxysilane, γ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylmethyldiethoxysilane, α-glycidoxypropylmethyldimethoxysilane, α-glycidoxypropylmethyldiethoxysilane, β-glycidoxypropylmethyldimethoxysilane, β-glycidoxypropylmethyldiethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldimethoxyethoxysilane, γ-glycidoxypropylmethyldiphenoxysilane, γ-glycidoxypropylethyldimethoxysilane, γ-glycidoxypropylethyldiethoxysilane, γ-glycidoxypropylethyldipropoxysilane, γ-glycidoxypropylvinyldimethoxysilane, and γ-glycidoxypropylvinyldiethoxysilane.

The inorganic oxide layer (II) may be formed by a plating method. Examples of the plating method include a dry plating method and a wet plating method.

Examples of the dry plating method include a physical vapor deposition (PVD) method such as sputtering, vacuum vapor deposition, and ion plating, and a chemical vapor deposition (CVD) method.

Examples of the inorganic oxide layer (II) when sputtering is performed include inorganic vapor deposited layers of SiO₂, SiC, TiC, TiN, TiO₂, ZnO, Fe₂O₃, V₂O₅, SnO₂, PbO, and Sb₂O₃. In order to obtain a transparent multilayer body, SiC, SiO₂, and ZnO are preferred, and a silicon oxide (SiO₂) layer is particularly preferred.

As the wet plating method, electroless plating is used. Among them, the dry plating method is preferred since an inorganic oxide layer that is highly dense is obtained.

In formation of the inorganic oxide layer by the plating method, the inorganic oxide layer may be formed directly on the resin layer (I) as a primer by the plating method. Since the curable resin layer (I) of the present invention contains the polysiloxane compound (A) and the inorganic oxide fine particles (C), the affinity of the curable resin layer for the inorganic oxide is high. Therefore, the inorganic oxide layer that is dense and has high adherence can be obtained.

A raw material for the inorganic oxide layer obtained by the plating method is preferably the same as the examples of the material for the coating liquid of the inorganic oxide.

An inorganic oxide layer that is a surface formed on the other material such as metal or quartz by plating may be used as the inorganic oxide layer (II). In this case, the inorganic oxide layer may be adhered to the curable resin layer (I) in an uncured or semi-cured state, and the curable resin layer (I) may be then cured.

### [Substrate]

The multilayer body of the present invention may further have a substrate in addition to the inorganic oxide layer (II). In this case, the substrate may be a substance layered on the other material.

The substrate is layered on the curable resin layer (I) in contact with a surface of the curable resin layer (I) opposite to the inorganic oxide layer (II).

The material for the substrate is not particularly limited. Examples of the substrate include a plastic layer of polyethylene terephthalate (PET), a resin (COP) having an alicyclic structure on a main chain in which a monomer is cycloolefin, a resin (COC) obtained by addition polymerization of a cyclic olefin (for example, norbornene) and an α-olefin (for example, ethylene), triacetylcellulose (TAC), a polyester, a polycarbonate, a polyimide, or the like; quartz, sapphire, glass, an optical film, a ceramic material, an inorganic oxide, a vapor deposition film (CVD, PVD, sputtering), a magnetic film, a reflective film, a metal such as Ni, Cu, Cr, Fe, and stainless steel, paper, spin on glass (SOG), and spin on carbon (SOC); a TFT array substrate, an electrode plate of PDP, a conductive substrate formed from ITO, metal, or the like, an insulating substrate, and a silicon-containing substrate of silicon, silicon nitride, polysilicon, silicon oxide, or amorphous silicon.

The substrate may be a single layer or a multilayer structure in which a plurality of materials are layered. A material for a portion of the surface of the substrate may be a different material or may be a bonded body of a metal and a plastic.

In order to further enhance the adherence to the curable resin layer (I) of the present invention, the surface of the plastic layer on which the curable resin layer (I) is layered may be subjected to publicly known surface treatment. Examples of such surface treatment include corona discharge treatment, plasma treatment, flame plasma treatment, electron beam-irradiation treatment, and ultraviolet irradiation treatment. One type of the surface treatment or treatment in which two or more types thereof are combined may be performed. In order to enhance the adherence to the curable resin layer (I), a primer coating or the like may be applied.

The thickness of the substrate is preferably 25 to 200 μm, and particularly preferably 40 to 150 μm.

The shape of the inorganic oxide layer (II) and the substrate is any shape. When the inorganic oxide layer (II) and the substrate are in contact with the curable resin layer (I), they may have a plane such as a plate shape or a film shape, a spherical shape or a curved surface, or unevenness. The inorganic oxide layer (II) and the substrate may be a composite of different materials. For example, the inorganic oxide layer (II) and the substrate may have a complicated shape in which a window made of plastic is fit into a door made of metal.

### [Multilayer Body]

The curable resin layer (I) of the present invention is characterized by including the primer composition containing the components (A) to (C). Since the composition contains an organic component and an inorganic component, the composition is characterized by favorable close contact with an organic layer and an inorganic layer. Therefore, the composition can be favorably used as a primer for the inorganic oxide layer in which a usual resin is difficult to be adhered.

In particular, when the layered surface of the substrate includes a plastic layer, the present invention exhibits the highest effect. This is because the curable resin layer (I) of the present invention is adhered to both the inorganic oxide layer and the plastic layer due to the components (A) and (B) contained in the curable resin layer (I). The curable resin layer (I) of the present invention is a particularly excellent inter-layer material, adhesive, or primer for bonding different materials that are generally less likely to form the multilayer body.

Since the curable resin layer (I) of the present invention is excellent in adherence in various environments (under conditions such as a hot condition and a humid condition), the curable resin layer (I) can impart the functions of the layers to the multilayer body.

When the multilayer body in which the curable resin layer (I) and the inorganic oxide layer (II) are disposed in this order is formed, the obtained multilayer body may have a sheet shape or a three-dimensional structure. The multilayer body may be in contact with the substrate or be bonded to the substrate. The multilayer body may protect the substrate by covering the substrate without contact.

In formation of the multilayer body that is integrated with the substrate, the curable resin layer (I) may be formed on the substrate, and then cured, and the inorganic oxide layer (II) may be formed. Alternatively, the curable resin layer (I) may be formed on the substrate, the inorganic oxide layer (II) may be then formed on the curable resin layer (I) in an uncured or semi-cured state, and the curable resin layer (I) may be completely cured. When the substrate is an active energy ray-curable plastic, the curable resin layer (I) may be formed on the substrate in an uncured or semi-cured state, and the substrate and the curable resin layer (I) may be completely cured before or after formation of the inorganic oxide layer (II). In this case, the adherence between the substrate and the curable resin layer (I) is further enhanced.

The multilayer body of the present application is excellent in hardcoat properties, antireflection performance, heat resistance, and water resistance, and therefore is particularly suitably usable as various antireflection materials and protecting materials. For example, the multilayer body is usable for protection and antireflection of a flat panel display, a building material, a housing facility, transport machines such as a vehicle, a ship, an aircraft, and a train, an electronic material, a recording material, an optical material, illumination, a packaging material, protection of an object mounted outside, covering an optical fiber, protection of resin glass, and the like.

### EXAMPLES

Next, the present invention will be described specifically using Examples and Comparative Examples. Unless otherwise indicated in Examples, “part(s)” and “%” are based on mass.

### Synthesis Example 1: Polysiloxane Compound (A): PSi-1

In a 0.5-L separable flask equipped with a stirrer and an air blowing tube, 138.5 parts by mass of 3-methacryloyltrimethoxysilane (KBM-503 available from Shin-Etsu Chemical Co., Ltd.), 100 parts by mass of propylene glycol monomethyl ether, 0.2 parts by mass of dibutylhydroxytoluene (BHT), 0.02 parts by mass of hydroquinone monomethyl ether (MEHQ), and 0.31 parts by mass of butyl acid phosphate (A-4 available from SC Organic Chemical Co., Ltd.) were placed. While the mixture was stirred at a liquid temperature of 75° C., 30.2 parts by mass of water was added dropwise.

After completion of dropwise addition, the mixture was stirred at 75° C. for 4 hours, reducing the temperature to 50° C. Subsequently, the pressure was reduced to 80 hPa, and methanol and water were distilled off until the liquid reached 70° C. The reaction product was diluted with propylene glycol monomethyl ether such that the solid content was 50 wt %, to obtain 230.7 parts by mass of PSi-1 that was a liquid containing a polysiloxane having a reactive group.

### Synthesis Example 2: Polysiloxane Compound (A): PSi-2

In a 0.5-L separable flask equipped with a stirrer and an air blowing tube, 55.4 parts by mass of KBM-503 (available from Shin-Etsu Chemical Co., Ltd., 3-methacryloxypropyltrimethoxysilane), 85.7 parts by mass of methyltrimethoxysilane (KBM-13 available from Shin-Etsu Chemical Co., Ltd.), 100 parts by mass of propylene glycol monomethyl ether, 0.2 parts by mass of dibutylhydroxytoluene (BHT), 0.02 parts by mass of hydroquinone monomethyl ether (MEHQ), and 0.43 parts by mass of A-4 (available from SC Organic Chemical Co., Ltd.) were placed. While the mixture was stirred at a liquid temperature of 75° C., 42.7 parts by mass of water was added dropwise.

After completion of dropwise addition, the mixture was stirred at 75° C. for 4 hours, reducing the temperature to 50° C. Subsequently, the pressure was reduced to 80 hPa, and methanol and water were distilled off until the liquid reached 70° C. The reaction product was diluted with propylene glycol monomethyl ether such that the solid content was 50 wt %, to obtain 243.3 g of PSi-2 that was a liquid containing a polysiloxane having a reactive group.

### Synthesis Example 3: Non-Reactive Polysiloxane Compound: PSi-3

In a 0.5-L separable flask equipped with a stirrer and an air blowing tube, 55.4 parts by mass of KBM-103 (available from Shin-Etsu Chemical Co., Ltd., phenyltrimethoxysilane), 85.7 parts by mass of methyltrimethoxysilane (KBM-13 available from Shin-Etsu Chemical Co., Ltd.), 100 parts by mass of propylene glycol monomethyl ether, 0.2 parts by mass of dibutylhydroxytoluene (BHT), 0.02 parts by mass of hydroquinone monomethyl ether (MEHQ), and 0.43 parts by mass of A-4 (available from SC Organic Chemical Co., Ltd.) were placed. While the mixture was stirred at a liquid temperature of 75° C., 42.7 parts by mass of water was added dropwise.

After completion of dropwise addition, the mixture was stirred at 75° C. for 4 hours, reducing the temperature to 50° C. Subsequently, the pressure was reduced to 80 hPa, and methanol and water were distilled off until the liquid reached 70° C. The reaction product was diluted with propylene glycol monomethyl ether such that the solid content was 50 wt %, to obtain 243.3 g of PSi-3 that was a liquid containing a polysiloxane having no reactive group.

### Synthesis Example 4: Polysiloxane-Silica Hybrid: HSP-1

In a 0.5-L separable flask equipped with a stirrer and an air blowing tube, 193.38 parts by mass of 3-methacryloyltrimethoxysilane (KBM-503 available from Shin-Etsu Chemical Co., Ltd.), 351.02 parts by mass of PGM-ST (unmodified colloidal silica, available from Nissan Chemical Corporation), 139.58 parts by mass of propylene glycol monomethyl ether, 0.2 parts by mass of dibutylhydroxytoluene (BHT), 0.02 parts by mass of hydroquinone monomethyl ether (MEHQ), and 0.142 parts by mass of butyl acid phosphate (A-4 available from SC Organic Chemical Co., Ltd.) were placed. While the mixture was stirred at a liquid temperature of 75° C., 42.1 parts by mass of water was added dropwise.

After completion of dropwise addition, the mixture was stirred at 75° C. for 4 hours, reducing the temperature to 50° C. Subsequently, the pressure was reduced to 80 hPa, and methanol and water were distilled off until the liquid reached 70° C. The reaction product was diluted with propylene glycol monomethyl ether such that the solid content was 50 wt %, to obtain 230.7 parts by mass of HSP-1 that was a liquid containing a polysiloxane having a reactive group.

### Example 1

### (Preparation of Composition)

5.00 parts by mass of PSi-1 synthesized as a polysiloxane compound (Psi), 8.33 parts by mass of PGM-ST (available from Nissan Chemical Corporation, unmodified silica, particle diameter: 15 nm, solid content: 30 wt %), 48.65 parts by mass of 2-hydroxyethyl isocyanurate triacrylate (M-315, available from TOAGOSEI CO., LTD.), and dipentaerythritol hexaacrylate (DPHA, available from Nippon Kayaku Co., Ltd.) were blended and stirred. In the obtained blend, Omnirad 754 (available from IGM Resins B.V., photoinitiator) as a photoradical initiator in an amount of 3 parts by mass relative to the total amount of a resin solid content and the solid content of inorganic filler, and BYK-333 (BYK Japan KK) in an amount of 0.1 parts by mass as a leveling agent were blended and stirred. Subsequently, the blend was diluted with methyl ethyl ketone (MEK), and the nonvolatile content was adjusted to 40 parts by mass, to obtain Composition 1.

### Examples 2 to 28 and Comparative Examples 1 to 5

A composition in each Example was obtained in the same manner as in Example 1 except that the blending ratio in blending was changed to each of the blending ratios listed in Tables 1 to 7.

In Tables, abbreviations each indicate the following meaning.
2140Z: “MEK-AC-2140Z” (available from Nissan Chemical Corporation, methacryloyl group surface-modified silica, particle diameter: 12 nm)
5140Z: “MEK-AC-5140Z” (available from Nissan Chemical Corporation, methacryloyl group surface-modified silica, particle diameter: 80 nm)
IPA-ST-L: trade name (available from Nissan Chemical Corporation, unmodified silica, particle diameter: 50 nm)
IPA-ST-ZL: trade name (available from Nissan Chemical Corporation, unmodified silica, particle diameter: 100 nm)
PETA: Pentaerythritol triacrylate
PU610: “Miramer PU610” (available from Miwon Specialty Chemical Co., Ltd., hexafunctional aliphatic urethane acrylate)

### (Production of Multilayer Body)

The composition obtained in each Example and each inorganic oxide layer listed in Tables 1 to 7 were used to produce a multilayer body under the following conditions. The obtained multilayer body was evaluated by test described later. The results are given together in Tables 1 to 7.

### (Application of Primer Composition)

The composition in each Example listed in Tables 1 to 7 was applied to a TAC film (thickness: 80 μm, Fuji Tac TD80ULP) by a bar coater such that the dried film thickness was about 5 μm, and dried for 1 minute by a drying machine of 70° C.

### (Curing of Primer Composition)

In ultraviolet irradiation, a high-pressure mercury lamp manufactured by GS Yuasa International Ltd. was used. The lamp output, the lamp height, and the conveyor speed were adjusted such that the irradiation energy per path was 300 mJ/cm² at a peak illuminance of 200 mW/cm² in a UV-A region of UV POWER PUCK II manufactured by EIT LLC. By a curing reaction under one-path irradiation (300 mJ/cm² in total), a curable resin layer (I) formed from the primer composition (primer layer) was obtained.

### (Layering of Inorganic Oxide Layer (II))

On the curable resin layer (I), an inorganic oxide layer (II) (sputtered layer) was formed by plasma CVD so as to have a thickness of 5 μm.

### (Sputtering Conditions)

Under the following conditions, Step 1 was performed, Step 2 was performed, and layering was then performed.
Step 1: Reverse sputtering, 1.0 Pa, Ar 20 sccm, RF 200 watt, 60 sec
Step 2: SiO₂ sputtering, 0.6 to 0.7 Pa, Ar 20 sccm, RF 200 watt, 50 nm

### (Test of Resistance to Heat and Humidity)

On a surface of the obtained multilayer body, a crosshatch pattern including 100 squares of 1 mmxl mm was formed. The multilayer body was placed in an environment at a temperature of 75° C. and a humidity of 95%, and then subjected to an adhesion test with cellophane tape every 100 hours until 1,200 hours. Thereafter, the state of the crosshatch pattern surface was observed and evaluated. In the evaluation of the adhesion test with cellophane tape, the state of the crosshatch pattern surface after a peeling test was observed. When at least one square was peeled, which position between the layers (sputtered layer-primer layer or primer layer-substrate layer) was peeled was confirmed, and an elapsed time was recorded as a peeling time in Tables. When peeling was not found even after a lapse of 1,200 hours, “>1,200 h” was wrote.

### (Measurement of Surface Roughness Ra of Primer Layer)

The arithmetic average roughness Ra (nm) of the surface of the primer layer was measured with an atomic force microscope (AFM).

TABLE 1

| | | | Example | Example | Example | Example | Example |
|---|---|---|---|---|---|---|---|
| | | Compound | 1 | 2 | 3 | 4 | 5 |
| Primer | (A) | Psi-1 | 2.5 | 40 | 2.5 | 5 | 10 |
| layer | | Psi-2 | | | | | |
| | (C) | PGM-ST | 0.2 | 5 | 22.5 | 20 | 15 |
| | (D) | HSP-1 | | | | | |
| | (B) | M-315 | 48.65 | 27.5 | 37.5 | 37.5 | 37.5 |
| | | DPHA | 48.65 | 27.5 | 37.5 | 37.5 | 37.5 |
| | Photoinitiator | Omnirad754 | 3 | 3 | 3 | 3 | 3 |
| | Leveling | BYK- | 0.1 | 0.1 | 0.1 | 0.1 | 0.1 |
| | agent | 333 | | | | | |

| Inorganic oxide layer | | SiO2 | SiO2 | SiO2 | SiO2 | SiO2 |
|---|---|---|---|---|---|---|
| Ratio of Psi | % Silica | 7.4% | 11.1% | 90.0% | 80.0% | 60.0% |
| (A) and ratio | % Psi | 92.6% | 88.9% | 10.0% | 20.0% | 40.0% |
| of silica (C) | | | | | | |
| Inorganic substance | | 2.7 | 45 | 25 | 25 | 25 |
| concentration | | | | | | |
| relative to total | | | | | | |
| solid content | | | | | | |
| Test of | Sputtered/ | 400 h | 500 h | 600 h | 800 h | 800 h |
| resistance to | primer | | | | | |
| heat and | Primer/ | >1200 h | 300 h | >1200 h | >1200 h | >1200 h |
| humidity | substrate | | | | | |

| | | | | | |
|---|---|---|---|---|---|
| Ra (nm) | <0.1 | <0.1 | <0.1 | <0.1 | <0.1 |

TABLE 2

| | | | Example | Example | Example | Example | Example |
|---|---|---|---|---|---|---|---|
| | | Compound | 6 | 7 | 8 | 9 | 10 |
| Primer | (A) | Psi-1 | 12.5 | 15 | 20 | 20 | 24 |
| layer | | Psi-2 | | | | | |
| | (C) | PGM-ST | 12.5 | 10 | 5 | 30 | 36 |
| | (D) | HSP-1 | | | | | |
| | (B) | M-315 | 37.5 | 37.5 | 37.5 | 25 | 20 |
| | | DPHA | 37.5 | 37.5 | 37.5 | 25 | 20 |
| | Photoinitiator | Omnirad754 | 3 | 3 | 3 | 3 | 3 |
| | Leveling | BYK-333 | 0.1 | 0.1 | 0.1 | 0.1 | 0.1 |
| | agent | | | | | | |

| Inorganic oxide layer | | SiO2 | SiO2 | SiO2 | SiO2 | SiO2 |
|---|---|---|---|---|---|---|
| Ratio of Psi | % Silica | 50.0% | 40.0% | 20.0% | 60.0% | 60.0% |
| (A) and ratio | % Psi | 50.0% | 60.0% | 80.0% | 40.0% | 40.0% |
| of silica (C) | | | | | | |
| Inorganic substance | | 25 | 25 | 25 | 50 | 60 |
| concentration relative | | | | | | |
| to total solid content | | | | | | |
| Test of | Sputtered/ | 800 h | 700 h | 600 h | 1000 h | 1000 h |
| resistance to | primer | | | | | |
| heat and | Primer/ | >1200 h | >1200 h | >1200 h | >1200 h | >1200 h |
| humidity | substrate | | | | | |

| | | | | | |
|---|---|---|---|---|---|
| Ra (nm) | <0.1 | <0.1 | <0.1 | <0.1 | <0.1 |

TABLE 3

| | | | Example | Example | Example | Example | Example |
|---|---|---|---|---|---|---|---|
| | | Compound | 11 | 12 | 13 | 14 | 15 |
| Primer | (A) | Psi-1 | 28 | | | 28 | 28 |
| layer | | Psi-2 | | | 28 | | |
| | (C) | PGM-ST | 42 | | 42 | | |
| | | 2140Z | | | | 42 | |
| | | 5140Z | | | | | 42 |
| | (D) | HSP-1 | | 60 | | | |
| | (B) | M-315 | 15 | 20 | 15 | 15 | 15 |
| | | DPHA | 15 | 20 | 15 | 15 | 15 |
| | Photoinitiator | Omnirad754 | 3 | 3 | 3 | 3 | 3 |
| | Leveling | BYK-333 | 0.1 | 0.1 | 0.1 | 0.1 | 0.1 |
| | agent | | | | | | |

| Inorganic oxide layer | | SiO2 | SiO2 | SiO2 | SiO2 | SiO2 |
|---|---|---|---|---|---|---|
| Ratio of Psi | % Silica | 60.0% | 60.0% | 60.0% | 60.0% | 60.0% |
| (A) and ratio | % Psi | 40.0% | 40.0% | 40.0% | 40.0% | 40.0% |
| of silica (C) | | | | | | |
| Inorganic substance | | 70 | 60 | 70 | 70 | 70 |
| concentration relative | | | | | | |
| to total solid content | | | | | | |
| Test of | Sputtered/ | 900 h | 1100 h | 900 h | 900 h | 900 h |
| resistance to | primer | | | | | |
| heat and | Primer/ | >1200 h | >1200 h | >1200 h | >1200 h | >1200 h |
| humidity | substrate | | | | | |

| | | | | | |
|---|---|---|---|---|---|
| Ra (nm) | <0.1 | <0.1 | <0.1 | <0.1 | 1.3 |

TABLE 4

| | | | Example | Example | Example | Example | Example |
|---|---|---|---|---|---|---|---|
| | | Compound | 16 | 17 | 18 | 19 | 20 |
| Primer | (A) | Psi-1 | 24 | 24 | 24 | 24 | 24 |
| layer | (C) | PGM-ST | 36 | 36 | 36 | 36 | 36 |
| | (D) | HSP-1 | | | | | |
| | (B) | M-315 | | 2 | 4 | 36 | 40 |
| | | DPHA | 40 | 38 | 36 | 4 | |
| | Photoinitiator | Omnirad754 | 3 | 3 | 3 | 3 | 3 |
| | Leveling | BYK-333 | 0.1 | 0.1 | 0.1 | 0.1 | 0.1 |
| | agent | | | | | | |

| Inorganic oxide | layer | SiO2 | SiO2 | SiO2 | SiO2 | SiO2 |
|---|---|---|---|---|---|---|
| Ratio of Psi | % Silica | 60.0% | 60.0% | 60.0% | 60.0% | 60.0% |
| (A) and ratio | % Psi | 40.0% | 40.0% | 40.0% | 40.0% | 40.0% |
| of silica (C) | | | | | | |
| Inorganic substance | | 70 | 70 | 70 | 70 | 70 |
| concentration relative | | | | | | |
| to total solid content | | | | | | |
| Test of | Sputtered/ | 700 h | 900 h | 1000 h | 1000 h | 900 h |
| resistance to | primer | | | | | |
| heat and | Primer/ | >1200 h | >1200 h | >1200 h | >1200 h | >1200 h |
| humidity | substrate | | | | | |

| | | | | | |
|---|---|---|---|---|---|
| Ra (nm) | <0.1 | <0.1 | <0.1 | <0.1 | <0.1 |

TABLE 5

| | | | Example | Example | Example | Example |
|---|---|---|---|---|---|---|
| | | Compound | 21 | 22 | 23 | 24 |
| Primer | (A) | Psi-1 | 24 | 24 | 24 | 24 |
| layer | (C) | PGM-ST | 36 | 36 | 27 | 18 |
| | | IPA-ST- | | | 9 | 18 |
| | | L | | | | |
| | (D) | HSP-1 | | | | |
| | (B) | M-315 | 20 | 20 | 20 | 20 |
| | | DPHA | | | 20 | 20 |
| | | PETA | 20 | | | |
| | | PU610 | | 20 | | |
| | Photoinitiator | Omnirad754 | 3 | 3 | 3 | 3 |
| | Leveling | BYK-333 | 0.1 | 0.1 | 0.1 | 0.1 |
| | agent | | | | | |

| Inorganic oxide layer | | SiO2 | SiO2 | SiO2 | SiO2 |
|---|---|---|---|---|---|
| Ratio of Psi | % Silica | 60.0% | 60.0% | 60.0% | 60.0% |
| (A) and ratio | % Psi | 40.0% | 40.0% | 40.0% | 40.0% |
| of silica (C) | | | | | |
| Inorganic substance | | 70 | 70 | 70 | 70 |
| concentration relative | | | | | |
| to total solid content | | | | | |
| Test of | Sputtered/ | 1000 h | 1000 h | 1000 h | 1000 h |
| resistance to | primer | | | | |
| heat and | | | | | |
| humidity | Primer/ | >1200 h | >1200 h | >1200 h | >1200 h |
| | substrate | | | | |

| | | | | |
|---|---|---|---|---|
| Ra (nm) | <0.1 | <0.1 | 1.0 | 1.5 |

TABLE 6

| | | | Example | Example | Example | Example |
|---|---|---|---|---|---|---|
| | | Compound | 25 | 26 | 27 | 28 |
| Primer | (A) | Psi-1 | 24 | 24 | 24 | 24 |
| layer | (C) | PGM-ST | 15 | | | |
| | | IPA-ST- | 21 | 36 | 18 | |
| | | L | | | | |
| | | IPA-ST- | | | 18 | 36 |
| | | ZL | | | | |
| | (D) | HSP-1 | | | | |
| | (B) | M-315 | 20 | 20 | 20 | 20 |
| | | DPHA | 20 | 20 | 20 | 20 |
| | Photoinitiator | Omnirad754 | 3 | 3 | 3 | 3 |
| | Leveling | BYK-333 | 0.1 | 0.1 | 0.1 | 0.1 |
| | agent | | | | | |

| Inorganic oxide layer | | SiO2 | SiO2 | SiO2 | SiO2 |
|---|---|---|---|---|---|
| Ratio of Psi | % Silica | 60.0% | 60.0% | 60.0% | 60.0% |
| (A) and ratio | % Psi | 40.0% | 40.0% | 40.0% | 40.0% |
| of silica (C) | | | | | |
| Inorganic substance | | 70 | 70 | 70 | 70 |
| concentration relative | | | | | |
| to total solid content | | | | | |
| Test of | Sputtered/ | 1000 h | 900 h | 800 h | 700 h |
| resistance to | primer | | | | |
| heat and | Primer/ | >1200 h | >1200 h | >1200 h | >1200 h |
| humidity | substrate | | | | |

| | | | | |
|---|---|---|---|---|
| Ra (nm) | 1.9 | 2.0 | 6.5 | 10.5 |

TABLE 7

| | | | Comparative | Comparative | Comparative | Comparative | Comparative |
|---|---|---|---|---|---|---|---|
| | | Compound | Example 1 | Example 2 | Example 3 | Example 4 | Example 5 |
| Primer | (A) | Psi-1 | | 50 | | | |
| layer | | Psi-2 | | | | | |
| | | Psi-3 | | | | | 40 |
| | (C) | PGM-ST | | | 25 | | 5 |
| | | IPA-ST-L | | | | 25 | |
| | (D) | HSP-1 | | | | | |
| | (B) | M-315 | 50 | 25 | 37.5 | 37.5 | 27.5 |
| | | DPHA | 50 | 25 | 37.5 | 37.5 | 27.5 |
| | Photoinitiator | Omnirad754 | 3 | 3 | 3 | 3 | 3 |
| | Leveling | BYK-333 | 0.1 | 0.1 | 0.1 | 0.1 | 0.1 |
| | agent | | | | | | |

| Inorganic oxide layer | | SiO2 | SiO2 | SiO2 | SiO2 | SiO2 |
|---|---|---|---|---|---|---|
| Ratio of Psi | % Silica | 0.0% | 0.0% | 100.0% | 100.0% | 11.1% |
| (A) and ratio | % Psi | 0.0% | 100.0% | 0.0% | 0.0% | 88.9% |
| of silica (C) | | | | | | |
| Inorganic substance | | 0 | 50 | 25 | 25 | 45 |
| concentration relative to | | | | | | |
| total solid content | | | | | | |
| Test of | Sputtered/ | 0 h | 500 h | 200 h | 300 h | 200 h |
| resistance to | primer | | | | | |
| heat and | Primer/ | >1200 h | 100 h | >1200 h | >1200 h | 100 h |
| humidity | substrate | | | | | |

| | | | | | |
|---|---|---|---|---|---|
| Ra (nm) | <0.1 | <0.1 | 2.1 | 10.7 | <0.1 |

From the results, the multilayer bodies in Examples 1 to 28 according to the present invention were excellent in adherence after the test of resistance to heat and humidity. On the other hand, the multilayer body in Comparative Example 1 in which the components (A) and (C) were not contained, the multilayer body in Comparative Example 2 in which the component (C) was not contained, the multilayer bodies in Comparative Examples 3 and 4 in which the component (A) was not contained, and the multilayer body in Comparative Example 5 in which the unreactive polysiloxane was used were inferior in adherence in a humid and hot environment.

1. A primer composition for inorganic oxide comprising:
a polysiloxane compound (A);
a compound having a reactive group (B) that is not the polysiloxane compound (A); and
inorganic oxide fine particles (C),
the polysiloxane compound (A) having a vinyl group and/or an epoxy group, a structural unit represented by a general formula (1) and/or a general formula (2), and a silanol group and/or a hydrolyzable silyl group, wherein
a content of the polysiloxane compound (A) is 2.5 to 40 mass % relative to a sum of the polysiloxane compound (A), the compound (B), and the inorganic oxide fine particles (C), 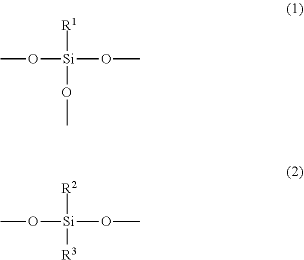
in the general formulae (1) and (2), R¹, R², and R³ are each independently a group having a polymerizable double bond selected from the group consisting of —R⁴—CH═CH₂, —R⁴—C(CH₃)═CH₂, —R⁴—O—CO—C(CH₃)═CH₂, —R⁴—O—CO—CH═CH₂, and a group represented by a general formula (3) below, or an alkyl group having 1 to 6 carbon atoms, a cycloalkyl group having 3 to 8 carbon atoms, an aryl group, an aralkyl group having 7 to 12 carbon atoms, or an epoxy group, and each R⁴ is independently a single bond or an alkylene group having 1 to 6 carbon atoms, 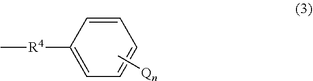
in the general formula (3), n is an integer of 1 to 5, a structure Q is —CH═CH₂ or —C(CH₃)═CH₂, and R⁴ is same as described above.

2. The primer composition for inorganic oxide according to claim 1, wherein
a ratio by mass (A)/(C) of a solid content of the polysiloxane compound (A) to a solid content of the inorganic oxide fine particles (C) is 10/90 to 80/20, and
a total content of the inorganic oxide fine particles (C) and the polysiloxane compound (A) is 70 mass % or less relative to a total solid content of the primer composition.

3. The primer composition for inorganic oxide according to claim 1, wherein the polysiloxane compound (A) is bonded to the inorganic oxide fine particles (C) through a siloxane bond to form an inorganic fine particle composite (D).

4. A cured product obtained by curing the primer composition for inorganic oxide according to claim 1.

5. A multilayer body comprising:
a curable resin layer (I) obtained by curing the primer composition for inorganic oxide according to claim 1; and
an inorganic oxide layer (II) containing an inorganic oxide.

6. The multilayer body according to claim 5, further comprising a substrate layer, wherein
the curable resin layer (I) and the inorganic oxide layer (II) in this order are layered on the substrate.

7. The multilayer body according to claim 6, wherein the substrate is a film having a thickness of 10 m to 1 mm.

8. The primer composition for inorganic oxide according to claim 2, wherein the polysiloxane compound (A) is bonded to the inorganic oxide fine particles (C) through a siloxane bond to form an inorganic fine particle composite (D).

9. A cured product obtained by curing the primer composition for inorganic oxide according to claim 2.

10. A cured product obtained by curing the primer composition for inorganic oxide according to claim 3.

11. A multilayer body comprising:
a curable resin layer (I) obtained by curing the primer composition for inorganic oxide according to claim 2; and
an inorganic oxide layer (II) containing an inorganic oxide.

12. A multilayer body comprising:
a curable resin layer (I) obtained by curing the primer composition for inorganic oxide according to claim 3; and
an inorganic oxide layer (II) containing an inorganic oxide.
